(19) United States
(12) Patent Application Publication
(10) Pub. No.: US 2026/0129997 A1
(43) Pub. Date: May 7, 2026

(54) LIGHT DETECTION ELEMENT

(71) Applicant: HAMAMATSU PHOTONICS K.K., Hamamatsu-shi (JP)

(72) Inventors: Masanori OKADA, Shizuoka (JP); Yuta TSUJI, Shizuoka (JP); Ryutaro TSUCHIYA, Shizuoka (JP); Shinya IWASHINA, Shizuoka (JP)

(73) Assignee: HAMAMATSU PHOTONICS K.K., Hamamatsu-shi (JP)

(21) Appl. No.: 19/374,328

(22) Filed: Oct. 30, 2025

(30) Foreign Application Priority Data
Nov. 5, 2024 (JP) 2024-193889

(51) Int. Cl. H10F 39/00; G01J 1/42; G01J 1/44; H10F 39/18

(52) U.S. Cl. CPC H10F 39/811; G01J 1/4228; G01J 1/44; H10F 39/014; H10F 39/024; H10F 39/18; H10F 39/8033; H10F 39/806; H10F 39/8063; G01J 2001/4466

(57) ABSTRACT

A light detection element includes a first semiconductor layer having a first main surface and a second main surface, a layer structure, metal wiring located inside of the layer structure, and a plurality of quenching elements. The first semiconductor layer includes a plurality of first semiconductor regions, a plurality of second semiconductor regions, and a plurality of third semiconductor regions. The thickness of the metal wiring is larger than the distance from the first surface of the metal wiring on a side opposite to the first main surface to the surface of the layer structure on a side opposite to the first main surface, and is larger than the distance from the second surface of the metal wiring on the first main surface side to the surface of the layer structure on the first main surface side.

### TECHNICAL FIELD

One aspect of the present disclosure relates to a light detection element.

### BACKGROUND

WO 2018/174090 A discloses, as an example of a light detection element, an imaging device including a first semiconductor layer formed on a semiconductor substrate, a second semiconductor layer formed on the first semiconductor layer and having a conductivity type opposite to that of the first semiconductor layer, a third semiconductor layer formed on the second semiconductor layer and having the same conductivity type as that of the second semiconductor layer, a pixel isolation portion defining a pixel region including the first semiconductor layer and the second semiconductor layer, a first electrode connected to the first semiconductor layer, and a second electrode connected to the second semiconductor layer.

In such a light detection element, light incident on each pixel region is photoelectrically converted and detected as a current signal. For example, in the imaging device described in WO 2018/174090 A, charge carriers are generated (photoelectrically converted) in the third semiconductor layer by incidence of light, and then the charge carriers are multiplied in the first semiconductor layer and the second semiconductor layer to which voltage is applied via the first electrode and the second electrode. The multiplied charge carriers are detected as current signals.

### SUMMARY

In the light detection element as described above, an avalanche photodiode is formed in each pixel, and charge carriers generated in the semiconductor layer by incidence of light are multiplied and detected by the avalanche photodiode. However, the charge carriers multiplied by the avalanche photodiode may recombine to generate secondary photons. The secondary photons can cause crosstalk. Specifically, there is a possibility that the secondary photons are incident on other pixels to generate new charge carriers. Such crosstalk reduces detection accuracy in the light detection element.

An object of one aspect of the present disclosure is to provide a light detection element capable of suppressing a decrease in detection accuracy.

A light detection element according to one aspect of the present disclosure is [1] “a light detection element including: a first semiconductor layer having a first main surface as a light incident surface and a second main surface opposite to the first main surface; a layer structure formed on the first main surface; metal wiring formed on the first main surface and at least partially located inside the layer structure; and a plurality of quenching elements located on the second main surface side with respect to the first semiconductor layer, in which the first semiconductor layer includes: a plurality of first semiconductor regions of a first conductivity type; a plurality of second semiconductor regions of a second conductivity type located closer to the second main surface than the plurality of first semiconductor regions and constituting a plurality of avalanche photodiodes together with the plurality of first semiconductor regions; and a plurality of third semiconductor regions of the first conductivity type located closer to the first main surface than the plurality of first semiconductor regions and having an impurity concentration higher than an impurity concentration of the plurality of first semiconductor regions, each of the plurality of quenching elements is electrically connected to a corresponding second semiconductor region among the plurality of second semiconductor regions, a trench extending so as to separate the plurality of third semiconductor regions from each other is formed in the first semiconductor layer, the metal wiring is formed on the first main surface so as to extend along the trench, and electrically connects the plurality of third semiconductor regions to each other, and a thickness of the metal wiring is larger than a distance from a first surface of the metal wiring on a side opposite to the first main surface to a surface of the layer structure on a side opposite to the first main surface, and is larger than a distance from a second surface of the metal wiring on a side of the first main surface to a surface of the layer structure on a side of the first main surface.”

In the light detection element, a trench extending so as to separate the plurality of third semiconductor regions from each other is formed in the first semiconductor layer. As a result, the secondary photons of the charge carriers multiplied in the avalanche photodiode can be prevented by the trench from being incident on the adjacent avalanche photodiodes through the third semiconductor region. In addition, the light detection element includes metal wiring formed on the first main surface so as to extend along the trench and at least partially located inside the layer structure, and a thickness of the metal wiring is larger than a distance from a first surface of the metal wiring on a side opposite to the first main surface to a surface of the layer structure on a side opposite to the first main surface, and larger than a distance from a second surface of the metal wiring on the first main surface side to a surface of the layer structure on the first main surface side. That is, since the thickness of the metal wiring with respect to the layer structure is large, the metal wiring can prevent the secondary photons from being incident on the adjacent avalanche photodiodes through the layer structure. In addition, in the light detection element, the first semiconductor layer includes the plurality of third semiconductor regions of the first conductivity type located closer to the first main surface than the plurality of first semiconductor regions and having an impurity concentration higher than the impurity concentration of the plurality of first semiconductor regions. As a result, the accumulation effect can be obtained by the concentration gradient of the impurities, and the detection accuracy can be improved. Further, the light detection element includes the plurality of quenching elements electrically connected to the plurality of second semiconductor regions. As a result, the light detection element can be stably operated in the Geiger mode. Therefore, according to the light detection element, a decrease in detection accuracy can be suppressed.

The light detection element according to one aspect of the present disclosure may be [2] “the light detection element according to [1], in which the layer structure includes a first insulating layer formed on the first main surface and a second insulating layer formed on the first insulating layer, and the metal wiring is located inside the first insulating layer and the second insulating layer.” In this case, for example, the first insulating layer and the second insulating layer can be formed of different materials, and a light detection element can be designed according to required performance. In addition, the secondary photons of the charge carriers multiplied in the avalanche photodiode can be prevented by the metal wiring from being incident on the adjacent avalanche photodiodes via the first insulating layer and the second insulating layer. That is, the crosstalk can be further prevented by the metal wiring, and a decrease in detection accuracy can be further suppressed.

The light detection element according to one aspect of the present disclosure may be [3] “the light detection element according to [2], in which a side surface of the metal wiring is in contact with the first insulating layer and the second insulating layer.” In this case, the crosstalk can be further prevented by the metal wiring, and a decrease in detection accuracy can be further suppressed.

The light detection element according to one aspect of the present disclosure may be [4] “the light detection element according to [1], in which the layer structure is a single insulating layer.” In this case, the light detection element can be configured by a simpler design.

The light detection element according to one aspect of the present disclosure may be [5] “the light detection element according to any one of [1] to [4], further including a lens portion disposed on the layer structure.” In this case, light incident on the light detection element can be efficiently condensed on the avalanche photodiode by the lens portion, and the detection accuracy can be improved.

The light detection element according to one aspect of the present disclosure may be [6] “the light detection element according to [5], in which a thickness of the metal wiring is larger than a distance from a surface of the lens portion on a side of the first main surface to the first surface.” In this case, since the thickness of the metal wiring is large, crosstalk can be further prevented by the metal wiring, and a decrease in the detection accuracy can be further suppressed.

The light detection element according to one aspect of the present disclosure may be [7] “the light detection element according to [5] or [6], further including a plurality of lens portions each configured to be the lens portion, in which each of the plurality of lens portions is disposed so as to overlap a corresponding avalanche photodiode among the plurality of avalanche photodiodes in a direction perpendicular to the first main surface, and an outer edge of each of the plurality of lens portions overlaps the trench when viewed from a direction perpendicular to the first main surface.” In this case, if the lens portion is not arranged, light traveling toward the trench (dead area) can be condensed on the avalanche photodiode by the lens portion. Therefore, the detection accuracy can be improved.

The light detection element according to one aspect of the present disclosure may be [8] “the light detection element according to any one of [1] to [4], in which the metal wiring is formed so as to cover the entire trench when viewed from a direction perpendicular to the first main surface, and each of the plurality of avalanche photodiodes is surrounded by the metal wiring when viewed from a direction perpendicular to the first main surface.” In this case, the crosstalk can be further suppressed by the metal wiring, and the detection accuracy can be further improved.

A light detection element according to one aspect of the present disclosure is [9] “a light detection element including: a first semiconductor layer having a first main surface as a light incident surface and a second main surface opposite to the first main surface; a layer structure having a first insulating layer formed on the first main surface, and a second insulating layer formed on the first insulating layer; metal wiring formed on the first main surface, at least a part of which is located inside the layer structure; and a plurality of quenching elements located on the second main surface side with respect to the first semiconductor layer, in which the first semiconductor layer includes: a plurality of first semiconductor regions of a first conductivity type; a plurality of second semiconductor regions of a second conductivity type located closer to the second main surface than the plurality of first semiconductor regions and constituting a plurality of avalanche photodiodes together with the plurality of first semiconductor regions; and a plurality of third semiconductor regions of the first conductivity type located closer to the first main surface than the plurality of first semiconductor regions and having an impurity concentration higher than an impurity concentration of the plurality of first semiconductor regions, each of the plurality of quenching elements is electrically connected to a corresponding second semiconductor region among the plurality of second semiconductor regions, a trench extending so as to separate the plurality of third semiconductor regions from each other is formed in the first semiconductor layer, the metal wiring is formed on the first main surface so as to extend along the trench, and electrically connects the plurality of third semiconductor regions to each other, and a surface of the metal wiring on a side opposite to the first main surface is located farther from the first main surface than a surface of the first insulating layer on a side opposite to the first semiconductor layer in a direction perpendicular to the first main surface.”

In the light detection element, a trench extending so as to separate the plurality of third semiconductor regions from each other is formed in the first semiconductor layer. As a result, the secondary photons of the charge carriers multiplied in the avalanche photodiode can be prevented by the trench from being incident on the adjacent avalanche photodiodes through the third semiconductor region. In addition, the light detection element includes metal wiring formed on the first main surface so as to extend along the trench and at least partially located inside the layer structure, in which a surface of the metal wiring on a side opposite to the first main surface is located farther from the first main surface than a surface of the first insulating layer on a side opposite to the first semiconductor layer in a direction perpendicular to the first main surface. As a result, since the thickness of the metal wiring is large, the metal wiring can prevent the secondary photons from being incident on the adjacent avalanche photodiodes through the layer structure. In addition, in the light detection element, the first semiconductor layer includes the plurality of third semiconductor regions of the first conductivity type located closer to the first main surface than the plurality of first semiconductor regions and having an impurity concentration higher than the impurity concentration of the plurality of first semiconductor regions. As a result, the accumulation effect can be obtained by the concentration gradient of the impurities, and the detection accuracy can be improved. Further, the light detection element includes the plurality of quenching elements electrically connected to the plurality of second semiconductor regions. As a result, the light detection element can be stably operated in the Geiger mode. Therefore, according to the light detection element, a decrease in detection accuracy can be suppressed.

According to one aspect of the present disclosure, it is possible to provide a light detection element capable of suppressing a decrease in detection accuracy.

### BRIEF DESCRIPTION OF THE DRAWINGS

FIG. 1 is a plan view schematically illustrating a light detection element according to an embodiment;

FIG. 2 is a partial cross-sectional view illustrating the light detection element illustrated in FIG. 1;

FIG. 3 is an enlarged view of a part of the cross-sectional view illustrated in FIG. 2;

FIG. 4 is a partial plan view of the light detection element illustrated in FIG. 1;

FIG. 5 is a cross-sectional view illustrating a layer structure and metal wiring of the light detection element illustrated in FIG. 1;

FIG. 6 is a partial plan view of the light detection element illustrated in FIG. 1;

FIG. 7 is an enlarged view of a part of the plan view illustrated in FIG. 6;

FIG. 8 is a view for describing a method of manufacturing the light detection element illustrated in FIG. 1;

FIG. 9 is a view for describing a method of manufacturing the light detection element illustrated in FIG. 1;

FIG. 10 is a view for describing a method of manufacturing the light detection element illustrated in FIG. 1;

FIG. 11 is a view for describing a method of manufacturing the light detection element illustrated in FIG. 1;

FIG. 12 is a partial cross-sectional view illustrating the light detection element according to the modification;

FIG. 13 is a partial cross-sectional view illustrating the light detection element according to the modification;

FIG. 14 is a cross-sectional view illustrating a layer structure and metal wiring of the light detection element illustrated in FIG. 13;

FIG. 15 is a cross-sectional view illustrating a layer structure and metal wiring of the light detection element according to the modification;

FIG. 16 is a cross-sectional view illustrating a layer structure and metal wiring of the light detection element according to the modification;

FIG. 17 is a cross-sectional view illustrating a layer structure and metal wiring of the light detection element according to the modification;

FIG. 18 is a partial cross-sectional view illustrating the light detection element according to the modification;

FIG. 19 is a partial cross-sectional view illustrating the light detection element according to the modification;

FIG. 20 is a partial plan view of the light detection element illustrated in FIG. 19; and

FIG. 21 is a partial plan view of the light detection element according to the modification.

### DETAILED DESCRIPTION

Hereinafter, embodiments of the present disclosure will be described in detail with reference to the drawings. Note that, in the drawings, the same or corresponding parts are denoted by the same reference signs, and redundant description will be omitted.

### Configuration of Light Detection Element

The light detection element according to the present embodiment is optoelectronic semiconductor element of the backside incidence type, and detects incident light as a current signal. In the present embodiment, the light detection element is configured as a SPAD (single photon avalanche diode) array. The light detection element configured as the SPAD array includes a plurality of cell units each including an avalanche photodiode and a quenching element connected in series with each other. Each cell unit constitutes a channel for independently transmitting a signal.

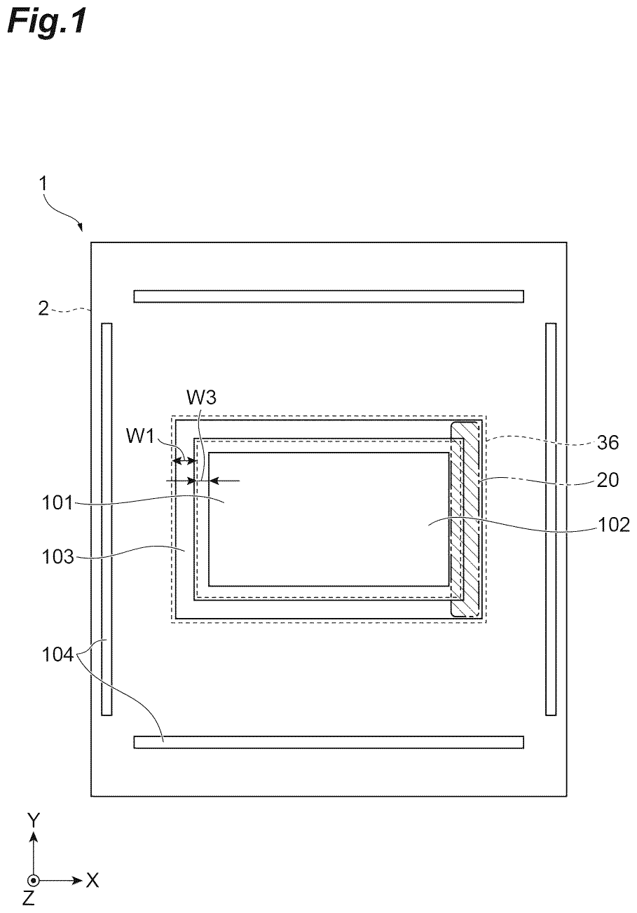

As illustrated in FIG. 1, a light detection element 1 according to the present embodiment is formed in a substantially rectangular plate shape. Hereinafter, a thickness direction of the light detection element 1 is referred to as a Z-axis direction, one direction perpendicular to the Z-axis direction is referred to as an X-axis direction, and a direction perpendicular to the Z-axis direction and the X-axis direction is referred to as a Y-axis direction. The light detection element 1 includes a light receiving area 101, a cathode area 102, an anode area 103, and a wire pad area 104.

The light receiving area 101 is a region where charge carriers are generated by incidence of light. In the light receiving area 101, a plurality of cell units (pixels) each including an avalanche photodiode to be described later are two-dimensionally arranged along a plane perpendicular to the Z-axis direction. In this example, the plurality of cell units are arranged on a straight line along the X-axis direction or the Y-axis direction. The cathode area 102 is an area where a cathode electrode (an opposite electrode layer 15 to be described later) electrically connected to the avalanche photodiode arranged in the light receiving area 101 is arranged. The cathode area 102 overlaps the light receiving area 101 in the Z-axis direction.

The anode area 103 is an area where an anode electrode (an electrode layer 17 to be described later) electrically connected to the avalanche photodiode disposed in the light receiving area 101 is disposed. The anode area 103 is located in a frame shape so as to surround light receiving area 101 and cathode area 102 when viewed from the Z-axis direction. The cathode electrode disposed in the cathode area 102 and the anode electrode disposed in the anode area 103 are electrically connected to the substrate included in the light detection element 1. The charge carriers generated in the avalanche photodiode in the light receiving area 101 are transmitted as a current signal to the substrate via the cathode electrode and the anode electrode. The wire pad area 104 is a region where external connection pads electrically connected to the substrate are disposed. The current signal is processed in, for example, a circuit included in the substrate, and then sent to the outside of the light detection element 1 via a pad disposed in the wire pad area 104.

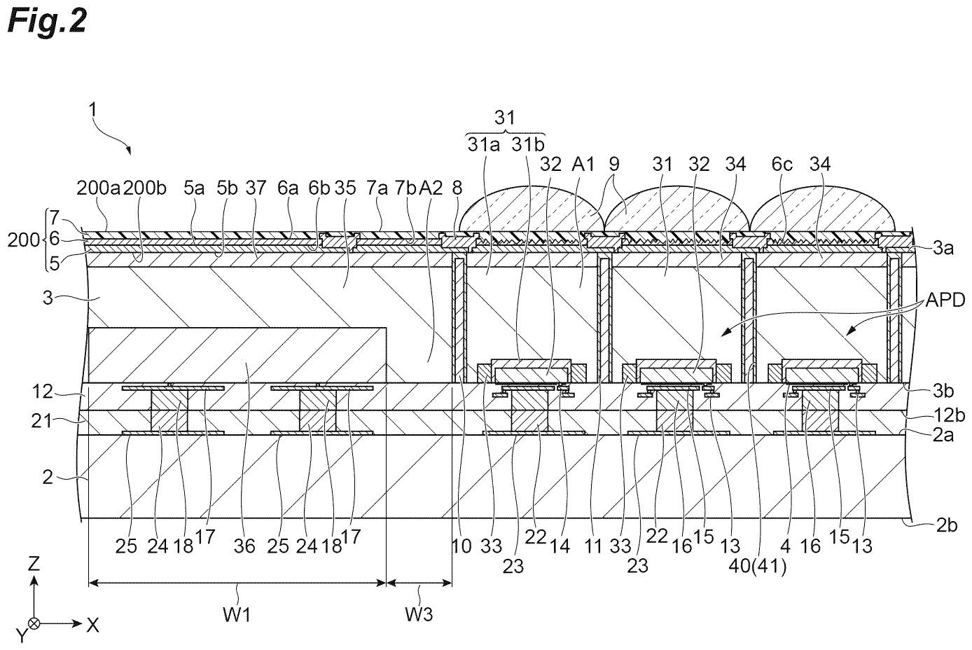

The configuration of the light detection element 1 will be described in more detail with reference to FIGS. 2 to 7. The light detection element 1 includes a substrate 2, a semiconductor layer (first semiconductor layer) 3, a plurality of pieces of insulating film 4, a layer structure 200, metal wiring 8, a plurality of lens portions 9, a metal portion 10, an insulating film 11, an insulating layer 12, a plurality of quenching elements 13, a plurality of wiring layers 14, a plurality of opposite electrode layers 15, a plurality of connection conductors 16, a plurality of electrode layers 17, a plurality of connection conductors 18, an insulating layer 21, a plurality of connection conductors 22, a plurality of electrode layers 23, a plurality of connection conductors 24, and a plurality of electrode layers 25. The layer structure 200 includes an insulating layer (first insulating layer) 5, a semiconductor layer (second semiconductor layer) 6, and an insulating layer (second insulating layer) 7.

The substrate 2 is a substrate on which an IC (integrated circuit) such as an ASIC is formed. The substrate 2 processes a current signal corresponding to a charge carrier generated in an avalanche photodiode APD described later. The substrate 2 is formed in, for example, a rectangular plate shape. The substrate 2 has a main surface 2a and a main surface 2b. The main surface 2a and the main surface 2b extend perpendicularly to the Z-axis direction. As illustrated in FIG. 1, for example, a plurality of pieces of wiring for applying a reverse bias voltage to an avalanche photodiode APD to be described later is formed in a region indicated by reference numeral 20 in the substrate 2. In FIG. 1, hatching is applied to a region 20 for convenience of description.

The semiconductor layer 3 is formed on the main surface 2a of the substrate 2 with the insulating layer 12 and the insulating layer 21 interposed therebetween. The semiconductor layer 3 has a main surface (first main surface) 3a and a main surface (second main surface) 3b. The main surface 3a and the main surface 3b extend perpendicularly to the Z-axis direction. That is, in this example, the Z-axis direction is a direction perpendicular to the main surface 3a. The main surface 3a constitutes a light incident surface of the light detection element 1. That is, the light detected by the light detection element 1 is incident inside the semiconductor layer 3 from the main surface 3a. The main surface 3b is located on the side opposite to the main surface 3a in the Z-axis direction. The main surface 3b is located closer to the substrate 2 than the main surface 3a.

The semiconductor layer 3 includes a plurality of semiconductor regions (a plurality of first semiconductor regions) 31, a plurality of semiconductor regions (a plurality of second semiconductor regions) 32, a plurality of semiconductor regions 33, a plurality of semiconductor regions (a plurality of third semiconductor regions) 34, a semiconductor region 35, a frame region 36, and a semiconductor region (a fourth semiconductor region) 37.

The plurality of semiconductor regions 31 are semiconductor regions doped with impurities and have a first conductivity type (P type in this example). The plurality of semiconductor regions 31 are separated from each other by a trench 40 to be described later, and are two-dimensionally arranged along a plane perpendicular to the Z-axis direction. Each semiconductor region 31 includes a first portion 31a and a second portion 31b. The first portion 31a is formed so as to cover the second portion 31b. The second portion 31b is formed in a region of the semiconductor region 31 on the main surface 3b side. The impurity concentration of the second portion 31b is higher than an impurity concentration of the first portion 31a.

The plurality of semiconductor regions 32 are semiconductor regions doped with impurities and have a second conductivity type (N type in this example) different from the first conductivity type. The plurality of semiconductor regions 32 are located closer to the main surface 3b than the plurality of semiconductor regions 31. The semiconductor regions 32 being located closer to the main surface 3b than the semiconductor regions 31 means that the center of the semiconductor regions 32 in the Z-axis direction is located closer to the main surface 3b than the center of the semiconductor regions 31. The semiconductor regions 32 are formed closer to the main surface 3b than to the center of the semiconductor layer 3 in the Z-axis direction. Each semiconductor region 32 is located so as to overlap the corresponding semiconductor region 31 among the plurality of semiconductor regions 31 in the Z-axis direction. The semiconductor region 32 is in contact with the second portion 31b of the semiconductor region 31.

The plurality of semiconductor regions 32 constitute a plurality of avalanche photodiodes APD together with the plurality of semiconductor regions 31. That is, the semiconductor layer 3 includes a plurality of avalanche photodiodes APD. The corresponding pair of semiconductor regions 31 and 32 constitute one avalanche photodiode APD. In the avalanche photodiode APD, the second portion 31b of the semiconductor region 31 and the semiconductor region 32 form an avalanche region. The avalanche region multiplies the charge carriers generated in the first portion 31a of the semiconductor region 31.

The plurality of semiconductor regions 33 are semiconductor regions doped with impurities and have the second conductivity type. The semiconductor regions 33 are guard ring regions. Each semiconductor region 33 is formed around the corresponding semiconductor region 32 when viewed from the Z-axis direction. The impurity concentration of the semiconductor region 33 is lower than an impurity concentration of the semiconductor region 32. That is, the impurity concentration of the semiconductor region 32 is higher than the impurity concentration of the semiconductor region 33.

The plurality of semiconductor regions 34 are semiconductor regions doped with impurities and have the first conductivity type. The plurality of semiconductor regions 34 are separated from each other by the trench 40 to be described later, and are two-dimensionally arranged along a plane perpendicular to the Z-axis direction. The plurality of semiconductor regions 34 are located closer to the main surface 3a than the plurality of semiconductor regions 31. That is, each semiconductor region 34 is formed on the corresponding semiconductor region 31. In this example, the surface of the semiconductor region 34 constitutes a part of the main surface 3a. An impurity concentration of the semiconductor region 34 is higher than an impurity concentration of the semiconductor region 31. As in this example, when the semiconductor region 31 has the first portion 31a and the second portion 31b having different impurity concentrations, the impurity concentration of the semiconductor region 31 corresponds to the concentration of the first portion 31a. That is, the impurity concentration of the semiconductor region 31 corresponds to not a portion having a high impurity concentration (second portion 31b) in contact with the semiconductor region 32 but a portion having a low impurity concentration (first portion 31a) located on the semiconductor region 34 side with the second portion 31b interposed therebetween.

The semiconductor region 35 is a semiconductor region doped with impurities and has the first conductivity type. The semiconductor region 35 is formed outside the plurality of semiconductor regions 31 when viewed from the Z-axis direction. The semiconductor region 35 is separated from the semiconductor region 31 by the trench 40 to be described later. The impurity concentration of the semiconductor region 35 may be the same as the impurity concentration of the first portion 31a of the semiconductor region 31.

The frame region 36 is a semiconductor region doped with impurities and has the first conductivity type. The frame region 36 is formed in a rectangular frame shape so as to surround the plurality of avalanche photodiodes APD (the semiconductor region 31 and the semiconductor region 32) when viewed from the Z-axis direction. The frame region 36 is continuously formed when viewed from the Z-axis direction. The frame region 36 is located closer to the main surface 3b than the semiconductor region 35. The frame region 36 being located closer to the main surface 3b than the semiconductor region 35 means that the center of the frame region 36 in the Z-axis direction is located closer to the main surface 3b than the center of the semiconductor region 35. The frame region 36 is formed closer to the main surface 3b than to the center of the semiconductor layer 3 in the Z-axis direction. The frame region 36 is located so as to overlap with a part of the semiconductor region 35 in the Z-axis direction (so as to be covered by the semiconductor region 35). The frame region 36 constitutes a part of the main surface 3b. The impurity concentration of the frame region 36 is higher than the impurity concentration of the semiconductor region 31 and the semiconductor region 35. The frame region 36 is electrically connected to the semiconductor region 31 via the semiconductor region 35, the semiconductor region 37, the metal wiring 8, and the semiconductor region 34. The frame region 36 is electrically connected to the power supply circuit of the substrate 2 via an electrode layer 17, a connection conductor 18, a connection conductor 24, and an electrode layer 25, which are to be described later.

The semiconductor region 37 is a semiconductor region doped with impurities and has the first conductivity type. The semiconductor region 37 is formed outside the plurality of semiconductor regions 31 when viewed from the Z-axis direction. The semiconductor region 37 is formed in a frame shape so as to surround the plurality of frame portions 41 (the plurality of semiconductor regions 34) when viewed from the Z-axis direction. The semiconductor region 37 is separated from the semiconductor region 34 by the trench 40 to be described later. The semiconductor region 37 is located closer to the main surface 3a than the frame region 36. The frame region 36 constitutes a part of the main surface 3a. The impurity concentration of the semiconductor region 37 is higher than the impurity concentration of the semiconductor region 31 and the semiconductor region 35.

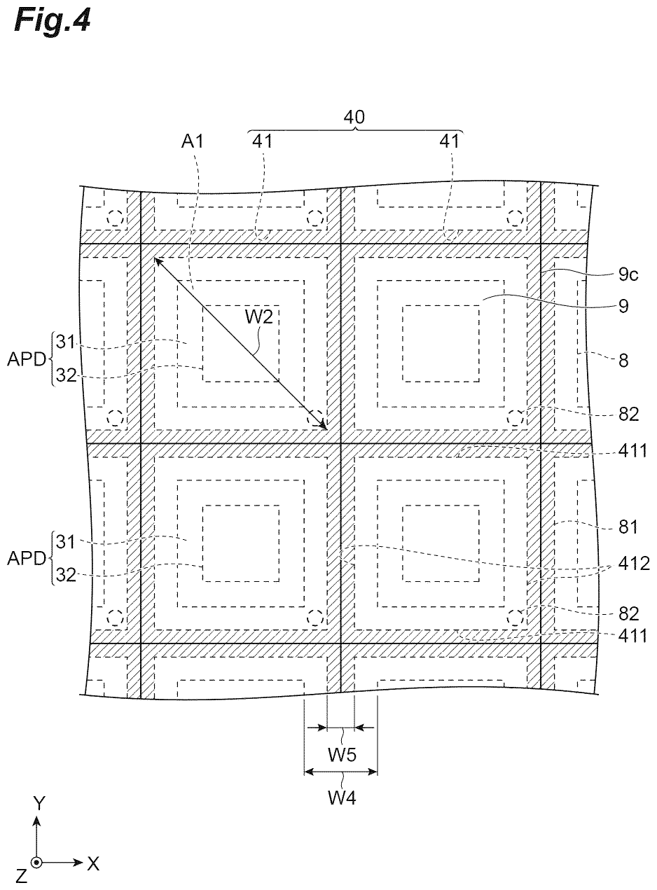

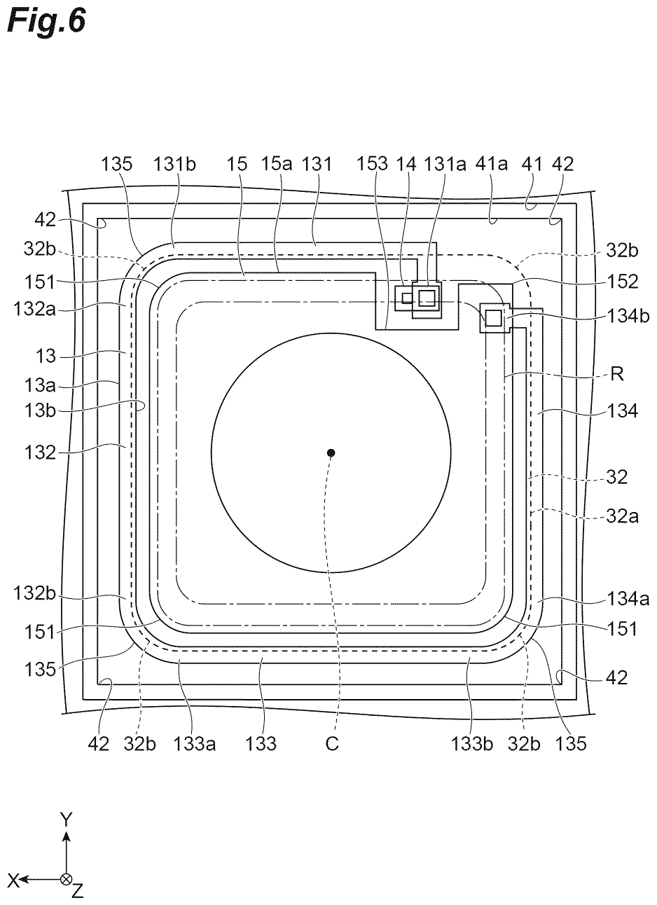

The trench 40 is formed in the semiconductor layer 3. The trench 40 is formed to extend from the main surface 3a to the main surface 3b. That is, the trench 40 penetrates the semiconductor layer 3 in the Z-axis direction. As illustrated in FIG. 4, the trench 40 extends in a mesh shape. In FIG. 4, hatching is applied to the trench 40 for convenience of description. The trench 40 includes a plurality of frame portions 41 extending in a frame shape when viewed from the Z-axis direction. In this example, each of the plurality of frame portions 41 extends in a rectangular frame shape. More specifically, each frame portion 41 includes a pair of first portions 411 extending along the X-axis direction and a pair of second portions 412 extending along the Y-axis direction. When viewed from the Z-axis direction, each of the width of the frame portion 41 in the X-axis direction (center-to-center distance between the second portions 412) and the width of the frame portion 41 in the Y-axis direction (center-to-center distance between the first portions 411) may be, for example, 5 μm or more and 25 μm or less. As illustrated in FIG. 6, the inner edge 41a of the trench 40 has four inner corner portions (nook portions) 42 when viewed from the Z-axis direction. In FIG. 6, for convenience of description, illustration of a part of the configuration of the substrate 2 and the like is omitted. The inner corner portion 42 corresponds to a portion (connection portion) where first portion 411 and second portion 412 intersect with each other. The inner corner portion 42 has a right angle when viewed from the Z-axis direction.

One semiconductor region 31, one semiconductor region 32, one semiconductor region 33, and one semiconductor region 34 are located inside each frame portion 41. The trench 40 extends so as to separate the plurality of semiconductor regions 31 from each other. The trench 40 extends so as to separate the plurality of semiconductor regions 34 from each other. One avalanche photodiode APD (a pair of semiconductor regions 31 and 32) is located inside each frame portion 41. The trench 40 extends so as to separate the plurality of avalanche photodiodes APD from each other when viewed from the Z-axis direction. Each frame portion 41 extends so as to surround the corresponding avalanche photodiode APD when viewed from the Z-axis direction.

As illustrated in FIGS. 1 and 2, the frame region 36 has a width W1 when viewed from the Z-axis direction. In FIG. 1, the frame region 36 is indicated by a broken line. The width W1 is a width in a direction perpendicular to the extending direction of the frame region 36. The width W1 is, for example, about 100 μm. As illustrated in FIG. 4, when viewed from the Z-axis direction, each of the plurality of regions A1 surrounded by the plurality of frame portions 41 in the semiconductor layer 3 has a width W2. The width W2 is the maximum width of the region A1. In this example, the region A1 has a rectangular shape when viewed in the Z-axis direction. Therefore, the width W2 is a length of a diagonal line of the region A1 when viewed from the Z-axis direction. When viewed from the Z-axis direction, the width W1 is larger than the width W2. The width W1 is twice or more the width W2. The width W1 may be four times or more the width W2.

As illustrated in FIGS. 1 and 2, when viewed from the Z-axis direction, a region A2 located between the frame region 36 and the plurality of frame portions 41 has a width W3. In this example, the region A2 extends in a rectangular frame shape when viewed from the Z-axis direction. The width W3 is a width in a direction perpendicular to the extending direction of the region A2. When viewed from the Z-axis direction, the width W1 is larger than the width W3. The width W1 is twice or more the width W3. The width W1 may be four times or more the width W3.

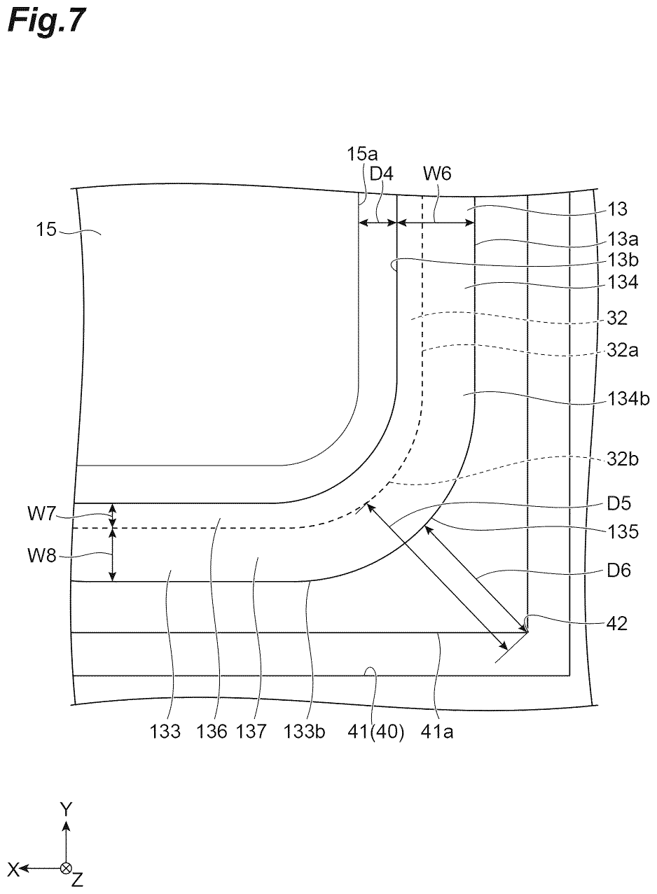

As illustrated in FIGS. 6 and 7, the semiconductor region 32 is located inside the frame portion 41 when viewed from the Z-axis direction. When viewed from the Z-axis direction, the outer edge 32a of the semiconductor region 32 has a substantially rectangular shape and extends along the inner edge 41a of the frame portion 41. The outer edge 32a extending along the inner edge 41a means that at least a part of the outer edge 32a is along the inner edge 41a, and the entire outer edge 32a is not necessarily along the inner edge 41a. In this example, the outer edge 32a includes a portion along each of the four sides of the substantially rectangular inner edge 41a.

When viewed from the Z-axis direction, the outer edge 32a of the semiconductor region 32 has a plurality of (four in this example) corner portions 32b. Each corner portion 32b has a round shape when viewed from the Z-axis direction. Each corner portion 32b is formed so as to protrude toward the corresponding inner corner portion 42 among the plurality of inner corner portions 42 included in the inner edge 41a of the frame portion 41. The corner portion 32b is curved so as to protrude toward the outside (inner corner portion 42) of the semiconductor region 32. As illustrated in FIG. 7, when viewed from the Z-axis direction, each corner portion 32b and the corresponding inner corner portion 42 are separated by a distance D5. The distance D5 is the shortest distance between the vertex of each corner portion 32b and the corresponding inner corner portion 42.

The plurality of pieces of insulating film 4 are formed on the main surface 3b of the semiconductor region 31. Each insulating film 4 is formed so as to cover the surface of the corresponding semiconductor region 32 on the main surface 3b side. In this example, the insulating film 4 is formed of a silicon nitride film (LP-SiN). The insulating film 4 can protect the semiconductor region 32 in the manufacturing process of the light detection element 1 and reduce variations in characteristics of the avalanche photodiode APD.

The layer structure 200 is formed on the main surface 3a of the semiconductor layer 3. As described above, the layer structure 200 includes the insulating layer 5, the semiconductor layer 6, and the insulating layer 7. The layer structure 200 has a surface 200a and a surface 200b. The surface 200a is located on the side opposite to the surface 200b in the Z-axis direction. The surface 200a is a surface of the layer structure 200 opposite to the main surface 3a. The surface 200b is a surface of the layer structure 200 on the main surface 3a side.

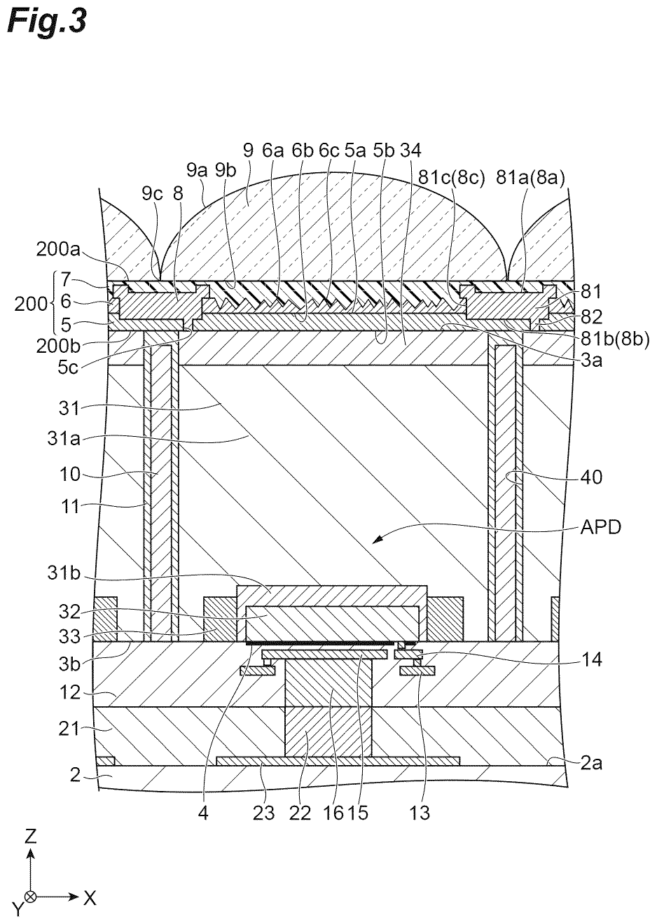

The insulating layer 5 is formed on main surface 3a of the semiconductor layer 3. The insulating layer 5 is formed directly on the main surface 3a. The insulating layer 5 is in contact with the main surface 3a. As illustrated in FIG. 3, the insulating layer 5 has a main surface 5a and a main surface 5b. The main surface 5a is a surface of the insulating layer 5 opposite to the semiconductor layer 3, and the main surface 5b is a surface of the insulating layer 5 on the semiconductor layer 3 side. The main surface 5b constitutes the surface 200b of the layer structure 200. The insulating layer 5 is formed so as to cover the semiconductor region 34 and the semiconductor region 37. A plurality of through holes (contact holes) 5c are formed in the insulating layer 5. In the plurality of through holes 5c, a plurality of contact portions 82 to be described later included in the metal wiring 8 are arranged. The insulating layer 5 is made of a material having electrically insulating properties. In this example, the insulating layer 5 is an oxide film formed of SiO₂.

The semiconductor layer 6 is formed on the main surface 3a of the semiconductor layer 3 with the insulating layer 5 interposed therebetween. The semiconductor layer 6 is formed directly on the insulating layer 5. The semiconductor layer 6 is in contact with the insulating layer 5. The semiconductor layer 6 is formed so as to cover the insulating layer 5. The semiconductor layer 6 is a non-doped semiconductor layer which is not doped with impurities. As illustrated in FIG. 2, the semiconductor layer 6 has a main surface 6a and a main surface 6b. The main surface 6a is a surface of the semiconductor layer 6 opposite to the insulating layer 5, and the main surface 6b is a surface of the semiconductor layer 6 on the insulating layer 5 side. That is, the main surface 6a is located on the side opposite to the main surface 6b in the Z-axis direction. The thickness of the semiconductor layer 6 may be, for example, about several μm (2 to 3 μm in this example).

A texture structure 6c having an uneven shape is formed on a surface of the semiconductor layer 6. The texture structure 6c is formed on the main surface 6a of the semiconductor layer 6. In this example, irregular (non-constant shape) uneven shapes are formed. The texture structure 6c is formed in a region overlapping the semiconductor region 31 on the main surface 6a in the Z-axis direction. That is, the texture structure 6c overlaps the plurality of avalanche photodiodes APD in the Z-axis direction. In this example, the texture structure 6c is not formed in a region overlapping with the semiconductor region 35 on the main surface 6a in the Z-axis direction. In the main surface 6a, a region where the texture structure 6c is formed is rougher (surface roughness is large) than a region where the texture structure 6c is not formed, and is not smooth.

The insulating layer 7 is formed on main surface 3a of the semiconductor layer 3 with the insulating layer 5 and the semiconductor layer 6 interposed therebetween. The insulating layer 7 is formed on the insulating layer 5 with the semiconductor layer 6 interposed therebetween. The insulating layer 7 is formed directly on the semiconductor layer 6. The insulating layer 7 is in contact with the main surface 6a of the semiconductor layer 6. As illustrated in FIG. 2, the insulating layer 7 has a main surface 7a and a main surface 7b. The main surface 7a is a surface of the insulating layer 7 opposite to the semiconductor layer 6, and the main surface 7b is a surface of the insulating layer 7 on the semiconductor layer 6 side. That is, the main surface 7a is located on the side opposite to the main surface 7b in the Z-axis direction. The main surface 7a constitutes the surface 200a of the layer structure 200. The insulating layer 7 is formed so as to cover the texture structure 6c formed in the semiconductor layer 6. The insulating layer 7 enters a recessed portion of the texture structure 6c (uneven shape). The insulating layer 7 is made of a material having electrically insulating properties. In this example, the insulating layer 7 is a resin layer formed of a resin material. The insulating layer 7 may be formed of a material other than resin.

The metal wiring 8 is disposed on the main surface 3a of the semiconductor layer 3. The metal wiring 8 extends along the trench 40 when viewed from the Z-axis direction. That is, the metal wiring 8 is formed on the main surface 3a so as to extend along the trench 40. The metal wiring 8 extends in a mesh shape when viewed from the Z-axis direction. At least a part (all in this example) of the metal wiring 8 is located inside the layer structure 200. That is, the metal wiring 8 is located inside the insulating layer 5, the semiconductor layer 6, and the insulating layer 7. The metal wiring 8 is formed of a metal material. The metal wiring 8 includes a main body portion 81 extending along the trench 40 and a plurality of contact portions 82 integrally formed with the main body portion 81.

The main body portion 81 is a wiring layer having a thickness in the Z-axis direction. The main body portion 81 has a surface 81a, a surface 81b, and a side surface 81c. The surface 81a is a surface of the main body portion 81 opposite to the main surface 3a of the semiconductor layer 3. The surface 81a constitutes a surface (first surface) 8a of the metal wiring 8 opposite to the main surface 3a. In the Z-axis direction, the surface 81a (surface 8a) is located farther from the main surface 3a than the main surface 5a of the insulating layer 5. The surface 8a protrudes from the insulating layer 5. That is, the surface 8a is exposed from the insulating layer 5. In this example, the surface 8a is located inside the insulating layer 7 and is in contact with the insulating layer 7.

The surface 81b is a surface of the main body portion 81 on the main surface 3a side. The surface 81b constitutes a surface (second surface) 8b of the metal wiring 8 on the main surface 3a side. That is, the surface 8b of the metal wiring 8 on the main surface 3a side corresponds not to the surface of the contact portion 82 described later but to the surface (surface 81b) of the main body portion 81 extending along the trench 40. The surface 81b (surface 8b) is located inside the insulating layer 5 and is in contact with the insulating layer 5. A part of the insulating layer 5 is located between the surface 81b and the trench 40. The side surface 81c is a surface connecting the surface 81a and the surface 81b. The side surface 81c constitutes a side surface 8c that connects the surface 8a and the surface 8b of the metal wiring 8. The side surface 8c (side surface 81c) is in contact with the insulating layer 5, the semiconductor layer 6, and the insulating layer 7.

The plurality of contact portions 82 are formed on the surface 81b of the main body portion 81. Each contact portion 82 is located in a corresponding through hole 5c formed in the insulating layer 5. The contact portion 82 is formed in a columnar shape. Each contact portion 82 is in contact with the corresponding semiconductor region 34 or semiconductor region 37. The metal wiring 8 electrically connects the plurality of semiconductor regions 34 to each other and electrically connects the plurality of semiconductor regions 34 to the semiconductor region 37.

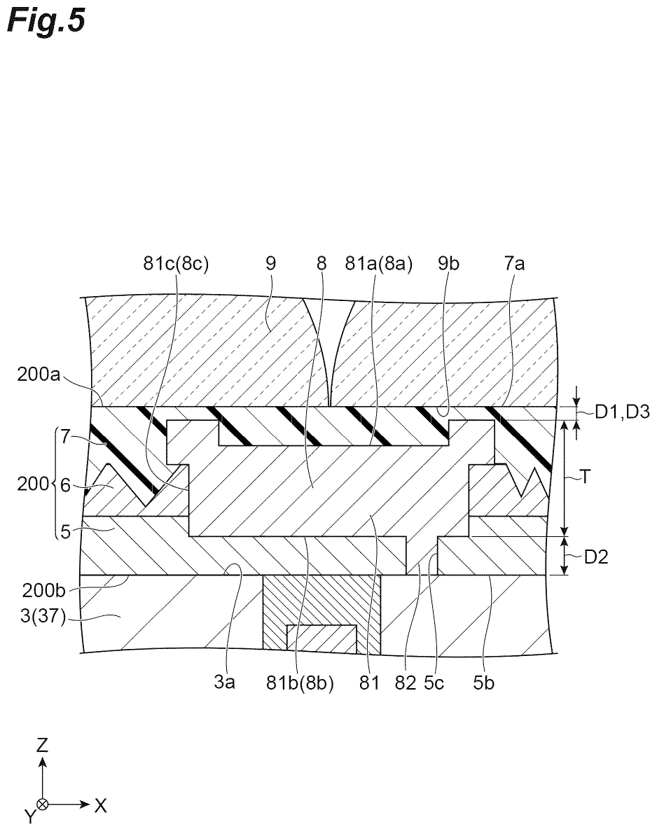

As illustrated in FIG. 5, the metal wiring 8 has a thickness T. The thickness T of the metal wiring 8 is the thickness of the main body portion 81, and is the maximum distance from the surface 81a (surface 8a) to the surface 81b (surface 8b) in this example. The thickness T is larger than a distance D1 from the surface 8a of the metal wiring 8 to the surface 200a of the layer structure 200 (the main surface 7a of the insulating layer 7). The thickness T is larger than a distance D2 from the surface 8b of the metal wiring 8 to the surface 200b of the layer structure 200 (the main surface 5b of the insulating layer 5). In this example, the thickness T is larger than the total of the distance D1 and the distance D2.

When viewed from the Z-axis direction, the metal wiring 8 is formed so as to cover the entire trench 40. The metal wiring 8 overlaps the trench 40 in the Z-axis direction. When viewed from the Z-axis direction, each of the plurality of avalanche photodiodes APD is surrounded by the metal wiring 8. When viewed from the Z-axis direction, a width W4 of the metal wiring 8 is larger than a width W5 of the trench 40. The width W4 is a width in a direction perpendicular to the extending direction of the metal wiring 8, and is a width of the main body portion 81. The width W5 is a width in a direction perpendicular to the extending direction of the trench 40.

The plurality of lens portions 9 are arranged on the layer structure 200. The lens portion 9 is formed directly on the insulating layer 7 of the layer structure 200. The lens portion 9 is in contact with the main surface 7a of the insulating layer 7. The lens portion 9 is disposed on the semiconductor layer 6 with the insulating layer 7 interposed therebetween. More specifically, the lens portion 9 is disposed on the texture structure 6c of the semiconductor layer 6 with the insulating layer 7 interposed therebetween. The insulating layer 7 functions as a spacer disposed between the lens portion 9 and the texture structure 6c. The lens portion 9 overlaps the texture structure 6c in the Z-axis direction. The plurality of lens portions 9 are two-dimensionally arranged along a plane perpendicular to the Z-axis direction. Each of the plurality of lens portions 9 is disposed so as to overlap the corresponding avalanche photodiode APD in the Z-axis direction. The lens portion 9 condenses the light incident onto the lens portion 9 on the avalanche photodiode APD.

The lens portion 9 has a surface 9a and a surface 9b. The surface 9a is a surface of the lens portion 9 opposite to the insulating layer 7. The surface 9a is a curved surface protruding to the side opposite to the insulating layer 7. The surface 9b is a surface of the lens portion 9 on the insulating layer 7 side. The surface 9b is a flat surface extending perpendicular to the Z-axis direction. The thickness T of the metal wiring 8 is larger than the distance D3 from the surface 9b to the surface 8a. When viewed from the Z-axis direction, the outer edge 9c of each of the plurality of lens portions 9 overlaps the trench 40. The outer edge 9c is located outside the outer edge of the semiconductor region 31. In this example, the outer edge 9c has a rectangular shape.

The metal portion 10 is formed inside the trench 40. The metal portion 10 is disposed so as to separate the adjacent avalanche photodiodes APD from each other. The metal portion 10 extends along the trench 40 when viewed from the Z-axis direction.

The insulating film 11 is formed inside the trench 40. The insulating film 11 is formed between the inner surface of the trench 40 and the metal portion 10. The insulating film 11 is made of a material having electrically insulating properties. In this example, the insulating film 11 is an oxide film formed of SiO₂. The insulating film 11 electrically insulates the semiconductor region 31 and the metal portion 10 from each other. The insulating film 11 electrically insulates the semiconductor region 34 and the metal portion 10 from each other.

The insulating layer 12 is formed on the main surface 3b of the semiconductor layer 3. The insulating layer 12 is formed directly on the main surface 3b. The insulating layer 12 is in contact with the main surface 3b. The insulating layer 12 is made of a material having electrically insulating properties. In this example, the insulating layer 12 is an oxide film formed of SiO₂.

The plurality of quenching elements 13 are located inside the insulating layer 12. The plurality of quenching elements 13 are located on the main surface 3b side with respect to the semiconductor layer 3. Each of the plurality of quenching elements 13 is electrically connected to the corresponding semiconductor region 32 and opposite electrode layer 15. As illustrated in FIG. 6, the quenching element 13 extends along the outer edge 32a of the semiconductor region 32 and overlaps the outer edge 32a of the semiconductor region 32 when viewed from the Z-axis direction. The quenching element 13 extending along the outer edge 32a of the semiconductor region 32 means that at least a part of the quenching element 13 is along the outer edge 32a, and the entire quenching element 13 is not necessarily along the outer edge 32a. In this example, the quenching element 13 includes a portion along each of the four sides of the substantially rectangular outer edge 32a.

In this example, the quenching element 13 is a quenching resistor formed in a frame plate shape having a thickness along the Z-axis direction. The quenching element 13 is formed in a substantially rectangular frame shape when viewed from the Z-axis direction. The quenching element 13 includes a pair of first portions 131 and 133 extending along the X-axis direction and a pair of second portions 132 and 134 extending along the Y-axis direction.

The end portion 131a of the first portion 131 (one end of the quenching element 13) is electrically connected to the semiconductor region 32 via the wiring layer 14. The quenching element 13 is connected in series with the semiconductor region 32 (avalanche photodiode APD). The other end portion 131b of the first portion 131 is continuous with the end portion 132a of the second portion 132. The other end portion 132b of the second portion 132 is continuous with the end portion 133a of the first portion 133. The other end portion 133b of the first portion 133 is continuous with the end portion 134a of the second portion 134. The other end portion 134b of the second portion 134 (the other end of the quenching element 13) is electrically connected to the opposite electrode layer 15. The end portion 134b of the second portion 134 is not continuous with the end portion 131a of the first portion 131. That is, the quenching element 13 is not formed in a closed frame when viewed from the Z-axis direction, but is formed in a frame shape in which a cut is partially formed (the end portion 131a and the end portion 134b are separated from each other).

Each quenching element 13 is located inside the corresponding frame portion 41 when viewed from the Z-axis direction. When viewed from the Z-axis direction, the outer edge 13a of the quenching element 13 extends along the inner edge 41a of the frame portion 41. The outer edge 13a extending along the inner edge 41a means that at least a part of the outer edge 13a is along the inner edge 41a, and the entire outer edge 13a is not necessarily along the inner edge 41a. In this example, the outer edge 13a includes a portion along each of the four sides of the rectangular inner edge 41a.

When viewed from the Z-axis direction, the outer edge 13a of the quenching element 13 has a plurality of (three in this example) corner portions 135. The three corner portions 135 correspond to a portion where the end portion 131b of the first portion 131 and the end portion 132a of the second portion 132 are continuous, a portion where the end portion 132b of the second portion 132 and the end portion 133a of the first portion 133 are continuous, and a portion where the end portion 133b of the first portion 133 and the end portion 134a of the second portion 134 are continuous.

Each corner portion 135 has a round shape when viewed from the Z-axis direction. Each corner portion 135 is formed so as to protrude toward the corresponding inner corner portion 42 among the plurality of inner corner portions 42 included in the inner edge 41a of the frame portion 41. The corner portion 135 is curved so as to protrude toward the outside (inner corner portion 42) of the quenching element 13. As illustrated in FIG. 7, when viewed from the Z-axis direction, each corner portion 135 and the corresponding inner corner portion 42 are separated by a distance D6. The distance D6 is the shortest distance between the vertex of each corner portion 135 and the corresponding inner corner portion 42. In this example, the distance D6 is smaller than the distance D5.

The plurality of opposite electrode layers 15 are located inside the insulating layer 12. The plurality of opposite electrode layers 15 are located on the main surface 3b side with respect to the semiconductor layer 3. Each of the plurality of opposite electrode layers 15 is electrically connected to the corresponding quenching element 13. The opposite electrode layer 15 faces the semiconductor region 32 in the Z-axis direction. The opposite electrode layer 15 overlaps at least a part of the semiconductor region 32 in the Z-axis direction. The opposite electrode layer 15 is located between the semiconductor layer 3 and the quenching element 13 in the Z-axis direction.

As illustrated in FIG. 6, the opposite electrode layer 15 is formed so as to include a peripheral edge region R when viewed from the Z-axis direction. The peripheral edge region R is a region located inside the outer edge 32a of the semiconductor region 32 when viewed from the Z-axis direction, and is a virtual annular region along the outer edge 32a of the semiconductor region 32. As described above, the outer edge 32a has a substantially rectangular shape. Therefore, in this example, the peripheral edge region R is a substantially rectangular annular region having an outer edge smaller than the outer edge 32a. The opposite electrode layer 15 including the peripheral edge region R means that the opposite electrode layer 15 includes at least a part of the peripheral edge region R, and does not necessarily include the entire peripheral edge region R. For example, the opposite electrode layer 15 may include a region of 50% or more or a region of 80% or more of the peripheral edge region R. When viewed from the Z-axis direction, the outer edge 15a is located inside the outer edge 32a.

The opposite electrode layer 15 is formed to extend from the central portion C of the semiconductor region 32 to the peripheral edge region R when viewed from the Z-axis direction. That is, the opposite electrode layer 15 is formed to spread so as to include the central portion C and the peripheral edge region R when viewed from the Z-axis direction. In this example, the size of the opposite electrode layer 15 is 50% or more of the size of the semiconductor region 32 when viewed from the Z-axis direction. The size of the opposite electrode layer 15 may be 80% or more of the size of the semiconductor region 32 when viewed from the Z-axis direction. When viewed from the Z-axis direction, the outer edge 15a of the opposite electrode layer 15 is located inside the outer edge 32a of the semiconductor region 32.

In this example, the opposite electrode layer 15 has a substantially rectangular shape when viewed in the Z-axis direction. When viewed from the Z-axis direction, the opposite electrode layer 15 has four corners (three corner portions 151 and one corner portion 152) formed so as to protrude toward the inner corner portion 42 of the trench 40. Each corner portion 151 has a round shape. Each corner portion 151 is curved so as to protrude toward the outside (inner corner portion 42) of the opposite electrode layer 15. On the other hand, the corner portion 152 is formed at a right angle. When viewed from the Z-axis direction, a cutout portion 153 is formed on one side of the opposite electrode layer 15. In a region corresponding to the cutout portion 153, a wiring layer 14 connected to one end of the quenching element 13 is disposed. The opposite electrode layer 15 is formed of, for example, a metal material such as aluminum.

Except for portions corresponding to both ends (end portions 131a and 134b) of the quenching element 13, the outer edge 15a of the opposite electrode layer 15 and the inner edge 13b of the quenching element 13 are separated from each other when viewed from the Z-axis direction. That is, when viewed from the Z-axis direction, the quenching element 13 is formed in a region outside the opposite electrode layer 15. When viewed from the Z-axis direction, the width W6 of the quenching element 13 is larger than the distance D4 from the outer edge 15a of the opposite electrode layer 15 to the inner edge 13b of the quenching element 13.

When viewed from the Z-axis direction, the quenching element 13 includes an overlapping portion 136 located along the inner edge 13b of the quenching element 13 and overlapping the semiconductor region 32, and a non-overlapping portion 137 located closer to the outer edge 13a of the quenching element 13 than the overlapping portion 136 and not overlapping the semiconductor region 32. When viewed from the Z-axis direction, a width W7 of overlapping portion 136 is smaller than a width W8 of non-overlapping portion 137.

The plurality of connection conductors 16 are formed inside the insulating layer 12. The plurality of connection conductors 16 are located on the substrate 2 side with respect to the plurality of opposite electrode layers 15. Each of the connection conductors 16 is formed in a columnar shape (a cylinder shape in this example) having a central axis along the Z-axis direction. Each of the connection conductors 16 is electrically connected to the corresponding opposite electrode layer 15 and the corresponding connection conductor 22 among the plurality of connection conductors 22 to be described later. The connection conductor 16 is formed of, for example, a metal material such as copper.

The plurality of electrode layers 17 are formed inside the insulating layer 12. The plurality of electrode layers 17 are located on the main surface 3b side with respect to the semiconductor layer 3. Each of the plurality of electrode layers 17 is electrically connected to the frame region 36 via wiring such as a connection conductor. The electrode layer 17 extends perpendicularly to the Z-axis direction and faces the frame region 36 in the Z-axis direction. The electrode layer 17 is formed of, for example, a metal material such as aluminum.

The plurality of connection conductors 18 are formed inside the insulating layer 12. The plurality of connection conductors 18 are located on the substrate 2 side with respect to the plurality of electrode layers 17. Each of the connection conductors 18 is formed in a columnar shape (a cylinder shape in this example) having a central axis along the Z-axis direction. Each of the connection conductors 18 is electrically connected to the corresponding electrode layer 17 and the corresponding connection conductor 24 among the plurality of connection conductors 24 to be described later. The connection conductor 18 is formed of, for example, a metal material such as copper.

The insulating layer 21 is formed on the main surface 2a of the substrate 2. The insulating layer 21 is formed directly on the main surface 2a. The insulating layer 21 is in contact with the main surface 2a. The insulating layer 21 is also in contact with the main surface 12b of the insulating layer 12 opposite to the semiconductor layer 3. The insulating layer 21 and the insulating layer 12 are stacked in this order on the main surface 2a. The insulating layer 21 is made of a material having electrically insulating properties. In this example, the insulating layer 21 is an oxide film formed of SiO₂.

The plurality of connection conductors 22 are formed inside the insulating layer 21. Each of the connection conductors 22 is formed in a columnar shape (a cylinder shape in this example) having a central axis along the Z-axis direction. Each of the connection conductors 22 is electrically connected to the corresponding connection conductor 16 and the corresponding electrode layer 23 among the plurality of electrode layers 23 to be described later. The connection conductor 22 is formed of, for example, a metal material such as copper.

The plurality of electrode layers 23 are formed inside the insulating layer 21. The plurality of electrode layers 23 are located on the substrate 2 side with respect to the plurality of connection conductors 22. Each of the plurality of electrode layers 23 is electrically connected to the corresponding connection conductor 22 and substrate 2. The electrode layer 23 extends perpendicularly to the Z-axis direction. The electrode layer 23 is formed of, for example, a metal material such as aluminum.

The plurality of connection conductors 24 are formed inside the insulating layer 21. Each of the connection conductors 24 is formed in a columnar shape (a cylinder shape in this example) having a central axis along the Z-axis direction. Each of the connection conductors 24 is electrically connected to the corresponding connection conductor 18 and the corresponding electrode layer 25 among the plurality of electrode layers 25 to be described later. The connection conductor 24 is formed of, for example, a metal material such as copper.

The plurality of electrode layers 25 are formed inside the insulating layer 21. The plurality of electrode layers 25 are located on the substrate 2 side with respect to the plurality of connection conductors 24. Each of the plurality of electrode layers 25 is electrically connected to the corresponding connection conductor 24 and substrate 2. The electrode layer 25 extends perpendicularly to the Z-axis direction. The electrode layer 25 is formed of, for example, a metal material such as aluminum.

The operation of the light detection element 1 described above will be described. In this example, the light detection element 1 is operated in a state in which a high reverse bias voltage is applied to the avalanche photodiode APD (Geiger mode). Specifically, first, a high voltage is applied to the avalanche photodiode APD in order to cause an avalanche effect in the avalanche photodiode APD. Specifically, a voltage is applied between the electrode layer 25 and the electrode layer 23 connected to the substrate 2 under the control of the power supply circuit of the substrate 2. The electrode layer 25 is electrically connected to each avalanche photodiode APD (the semiconductor region 31 and the semiconductor region 32) via the connection conductor 24, the connection conductor 18, the electrode layer 17, the frame region 36, the semiconductor region 35, the semiconductor region 37, the metal wiring 8, and the semiconductor region 34. In addition, the electrode layer 23 is electrically connected to the avalanche photodiode APD via the connection conductor 22, the connection conductor 16, the opposite electrode layer 15, the quenching element 13, and the wiring layer 14. Therefore, a voltage is applied to the avalanche photodiode APD by applying a voltage between the electrode layer 25 and the electrode layer 23.

Subsequently, light to be detected is incident on the avalanche photodiode APD. After being condensed by the lens portion 9, the light passes through the insulating layer 7, the semiconductor layer 6, and the insulating layer 5 in this order, and is incident on the semiconductor region 31 from the main surface 3a. Charge carriers are generated in the semiconductor region 31 by the incident light. The generated charge carriers are multiplied in the avalanche region configured by the second portion 31b of the semiconductor region 31 and the semiconductor region 32. The multiplied charge carriers are sent as current signals to the substrate 2 for each avalanche photodiode APD (for each cell unit) divided by the trench 40. The current signal is sent to the substrate 2 via the opposite electrode layer 15, the electrode layer 17, and the like. The circuit included in the substrate 2 processes the received current signal to generate a digital signal indicating the light incident on the light detection element 1. The signal processed by the circuit of the substrate 2 is sent to the outside of the light detection element 1 via the pad disposed in the wire pad area 104.

### Method for Manufacturing Light Detection Element

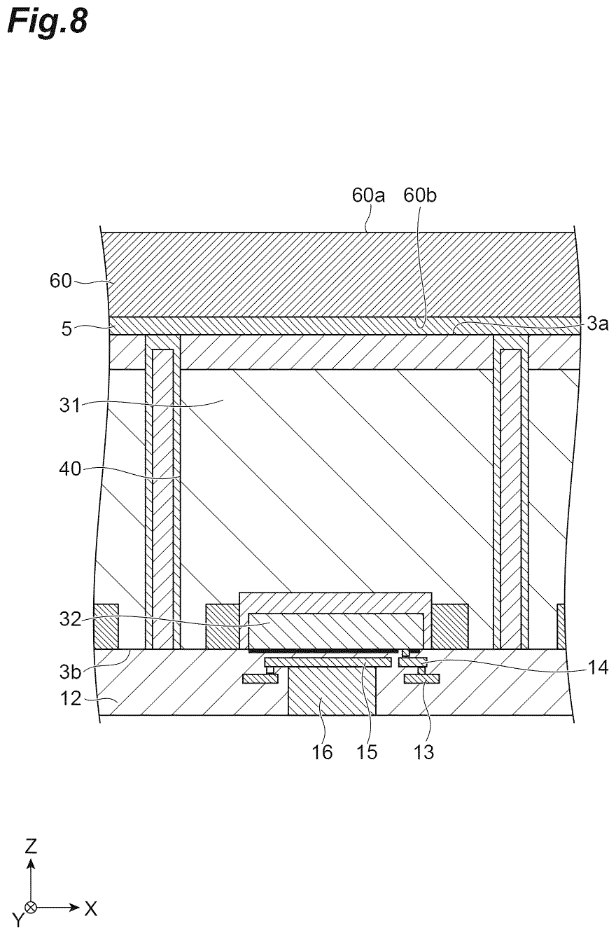

Next, a method for manufacturing the light detection element 1 will be described. First, as illustrated in FIG. 8, a layer stack in which the insulating layer 12, the semiconductor layer 3, the insulating layer 5, and the semiconductor layer 60 are stacked in this order is prepared. The semiconductor layer 60 is a layer that becomes the semiconductor layer 6 through the manufacturing process of the light detection element 1 (a layer corresponding to the semiconductor layer 6). In this example, the semiconductor layer 60 is a bulk layer. The semiconductor layer 60 is formed on the main surface 3a of the semiconductor layer 3 with the insulating layer 5 interposed therebetween. The semiconductor layer 60 is formed directly on the insulating layer 5. The semiconductor layer 60 is in contact with the insulating layer 5. The semiconductor layer 60 is formed so as to cover the insulating layer 5. The semiconductor layer 60 is a non-doped semiconductor layer which is not doped with impurities. The semiconductor layer 60 has a main surface 60a and a main surface 60b. The main surface 60a is a surface of the semiconductor layer 60 opposite to the insulating layer 5, and the main surface 60b is a surface of the semiconductor layer 60 on the insulating layer 5 side. The main surface 60a is located on the side opposite to the main surface 60b in the Z-axis direction. The thickness of the semiconductor layer 60 is larger than the thickness of the semiconductor layer 6. A thickness of the semiconductor layer 60 may be, for example, about several hundred μm. In this example, the thickness of the semiconductor layer 60 is 600 μm or more.

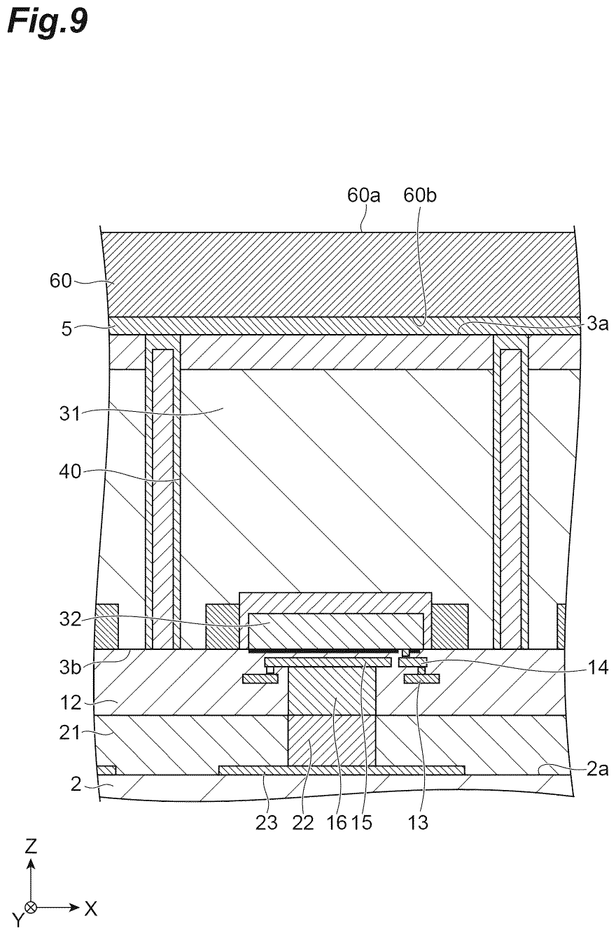

Subsequently, as illustrated in FIG. 9, a layer stack of the substrate 2 and the insulating layer 21 is prepared, and the insulating layer 12 and the insulating layer 21 are bonded to each other. At this time, the insulating layer 12 and the insulating layer 21 are aligned so that the connection conductor 16 in the insulating layer 12 and the connection conductor 22 in the insulating layer 21 are connected to each other and the connection conductor 18 in the insulating layer 12 and the connection conductor 24 in the insulating layer 21 are connected to each other (see FIG. 2).

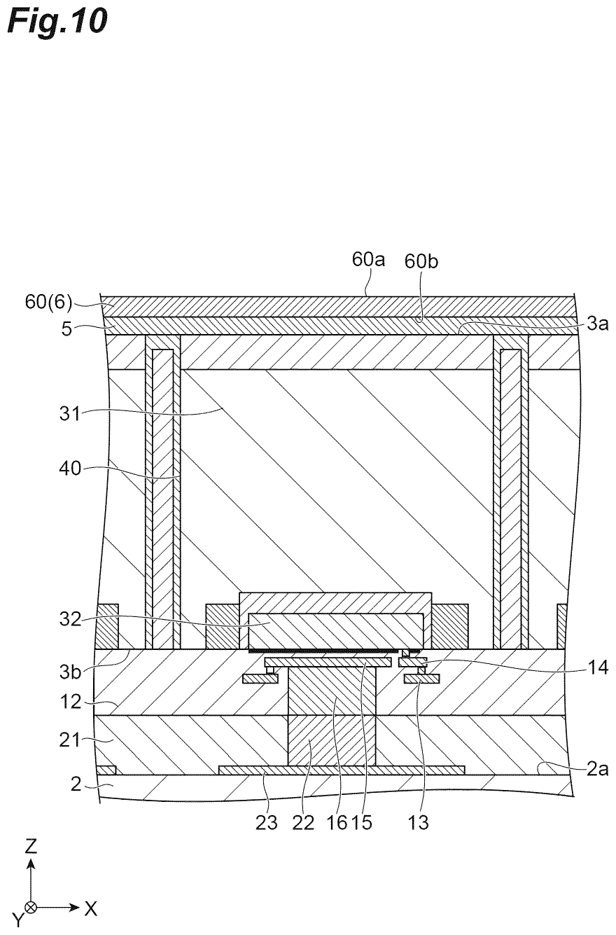

Subsequently, as illustrated in FIG. 10, the semiconductor layer 60 is polished and thinned to form the semiconductor layer 6. Specifically, the main surface 60a of the semiconductor layer 60 is polished until the thickness of the semiconductor layer 60 becomes, for example, about several tens μm. In this example, the main surface 60a is polished so that the thinned semiconductor layer 60 (semiconductor layer 6) has a thickness of 10 μm or less (2 to 3 μm in this example).

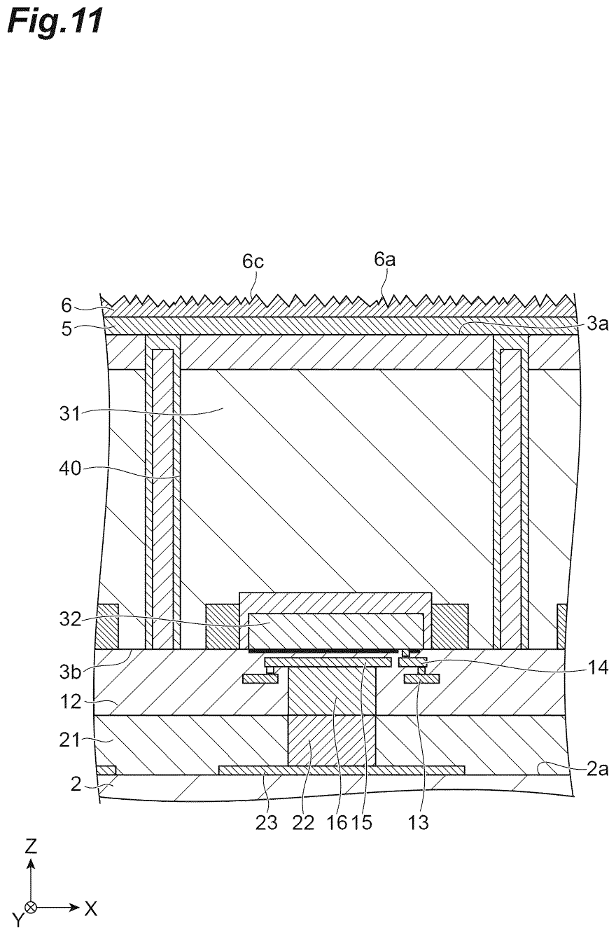

Subsequently, a texture structure 6c having an uneven shape is formed on a surface of the semiconductor layer 6. As illustrated in FIG. 11, the texture structure 6c is formed on the main surface 6a of the semiconductor layer 6 opposite to the insulating layer 5. In this example, the texture structure 6c is formed by etching the main surface 6a. The etching may be wet etching using a liquid etching agent.

Subsequently, as illustrated in FIG. 3, the insulating layer 7, the metal wiring 8, and the lens portion 9 are formed. First, the insulating layer 5 and the semiconductor layer 6 are partially removed, and the metal wiring 8 is formed at the removed portion. Subsequently, the insulating layer 7 is formed so as to cover the texture structure 6c and the metal wiring 8. Subsequently, the plurality of lens portions 9 are disposed on the insulating layer 7. Through the above process, the light detection element 1 is manufactured.

### Operations and Effects

In the light detection element 1, the trench 40 extending so as to separate the plurality of semiconductor regions 34 from each other is formed in the semiconductor layer 3. As a result, the secondary photons of the charge carriers multiplied in the avalanche photodiode APD can be prevented by the trench 40 from being incident on the adjacent avalanche photodiodes APD through the semiconductor region 34. In addition, the light detection element 1 is formed on the main surface 3a so as to extend along the trench 40, and includes the metal wiring 8 located inside the layer structure 200. The thickness T of the metal wiring 8 is larger than the distance D1 from the surface 8a of the metal wiring 8 to the surface 200a of the layer structure 200, and is larger than the distance D2 from the surface 8b of the metal wiring 8 to the surface 200b of the layer structure 200. In addition, in the Z-axis direction, the surface 8a of the metal wiring 8 is located farther from the main surface 3a than the main surface 5a of the insulating layer 5. That is, since the thickness T of the metal wiring 8 with respect to the layer structure 200 is large, the metal wiring 8 can prevent the secondary photons from being incident on the adjacent avalanche photodiodes APD through the layer structure 200. In addition, in the light detection element 1, the semiconductor layer 3 includes the semiconductor region 34 of the first conductivity type located closer to the main surface 3a than the plurality of semiconductor regions 31 and having an impurity concentration higher than the impurity concentration of the plurality of semiconductor regions 31. As a result, the accumulation effect can be obtained by the concentration gradient of the impurities, and the detection accuracy can be improved. Further, the light detection element 1 includes the plurality of quenching elements 13 electrically connected to the plurality of semiconductor regions 32. As a result, the light detection element 1 can be stably operated in the Geiger mode. Therefore, according to the light detection element 1, a decrease in detection accuracy can be suppressed.

The layer structure 200 includes the insulating layer 5 formed on the main surface 3a and the insulating layer 7 formed on the insulating layer 5. The metal wiring 8 is located inside the insulating layer 5 and the insulating layer 7. As a result, for example, the insulating layer 5 and the insulating layer 7 can be formed of different materials, and the light detection element 1 can be designed according to required performance. In addition, the secondary photons of the charge carriers multiplied in the avalanche photodiode APD can be prevented by the metal wiring 8 from being incident on the adjacent avalanche photodiodes APD via the insulating layer 5 and the insulating layer 7. That is, the crosstalk can be further prevented by the metal wiring 8, and a decrease in detection accuracy can be further suppressed.

The side surface 8c of the metal wiring 8 is in contact with the insulating layer 5 and the insulating layer 7. As a result, the crosstalk can be further prevented by the metal wiring 8, and a decrease in detection accuracy can be further suppressed.

The light detection element 1 includes the lens portion 9 arranged on the layer structure 200. As a result, light incident on the light detection element 1 can be efficiently condensed on the avalanche photodiode APD by the lens portion 9, and the detection accuracy can be improved.

The thickness T of the metal wiring 8 is larger than the distance D3 from the surface 9b of the lens portion 9 to the surface 8a of the metal wiring 8. As a result, since the thickness T of the metal wiring 8 is large, crosstalk can be further prevented by the metal wiring 8, and a decrease in the detection accuracy can be further suppressed.

The light detection element 1 includes a plurality of lens portions 9. Each of the plurality of lens portions 9 is disposed so as to overlap the corresponding avalanche photodiode APD in the Z-axis direction. When viewed from the Z-axis direction, the outer edge 9c of each of the plurality of lens portions 9 overlaps the trench 40. As a result, if the lens portion 9 is not arranged, light traveling toward the trench 40 (dead area) can be condensed on the avalanche photodiode APD by the lens portion 9. Therefore, the detection accuracy can be improved.

When viewed from the Z-axis direction, the metal wiring 8 is formed so as to cover the entire trench 40. When viewed from the Z-axis direction, each of the plurality of avalanche photodiodes APD is surrounded by the metal wiring 8. As a result, the crosstalk can be further suppressed by the metal wiring 8, and the detection accuracy can be further improved.

### Modifications

The present disclosure is not limited to the above embodiment. Hereinafter, modifications of the above-described embodiment will be described. In the following description, differences from the above-described embodiment will be mainly described, and description of common points may be omitted.

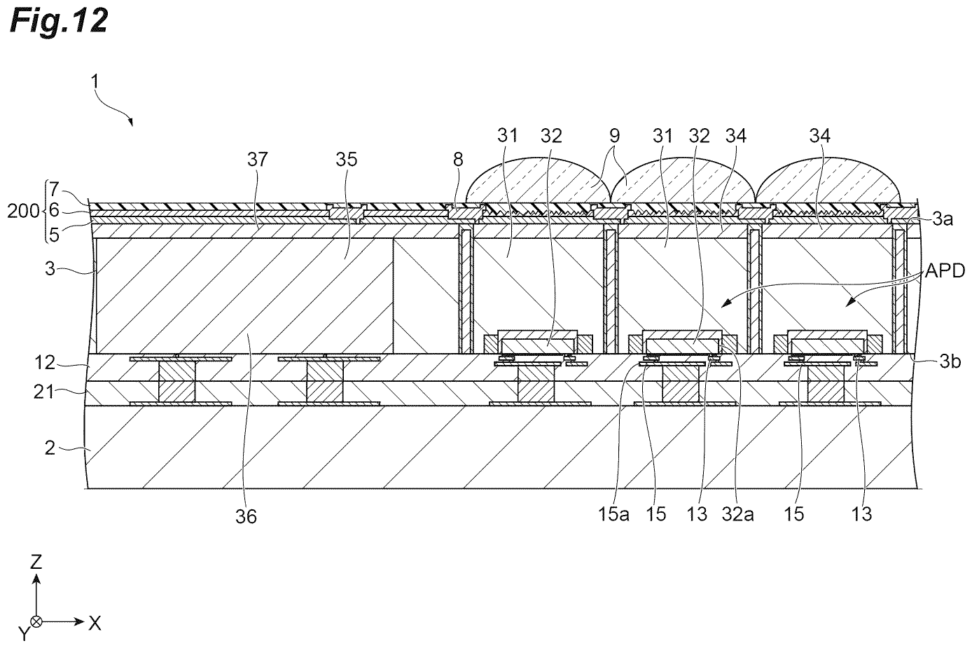

For example, as illustrated in FIG. 12, the frame region 36 may be formed to extend from the main surface 3b of the semiconductor layer 3 to the semiconductor region 37 in the Z-axis direction. In this example, the frame region 36 is formed so as to penetrate the semiconductor region 35 in the Z-axis direction. The frame region 36 is directly connected to the semiconductor region 37 without interposing the semiconductor region 35. As described above, since the frame region 36 is formed to reach (connect) the semiconductor region 37, the resistance between the frame region 36 and the semiconductor region 37 is reduced, and the potential gradient, the voltage drop, and the heat generation when the bias is applied to the avalanche photodiode APD via the frame region 36 and the semiconductor region 37 are suppressed. Therefore, a decrease in detection accuracy can be further suppressed.

As illustrated in FIG. 12, the quenching element 13 may be located between the semiconductor layer 3 and the opposite electrode layer 15 in the Z-axis direction. That is, the positions of the quenching element 13 and the opposite electrode layer 15 in the Z-axis direction may be opposite to those in the first embodiment described above. As shown in FIG. 12, when viewed from the Z-axis direction, at least a part of the outer edge 15a of the opposite electrode layer 15 may be located outside the outer edge 32a of the semiconductor region 32.

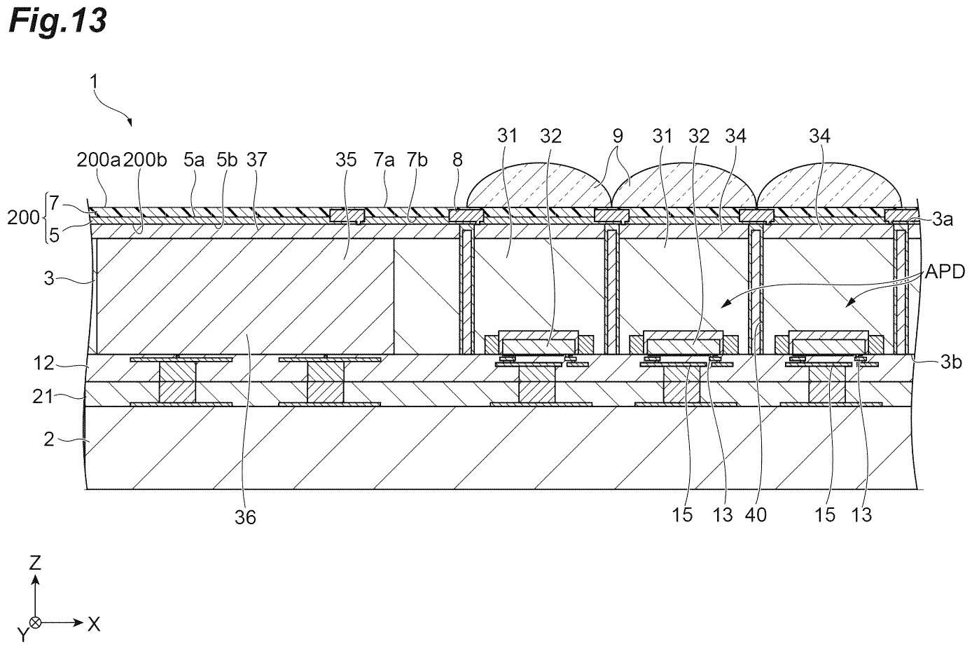

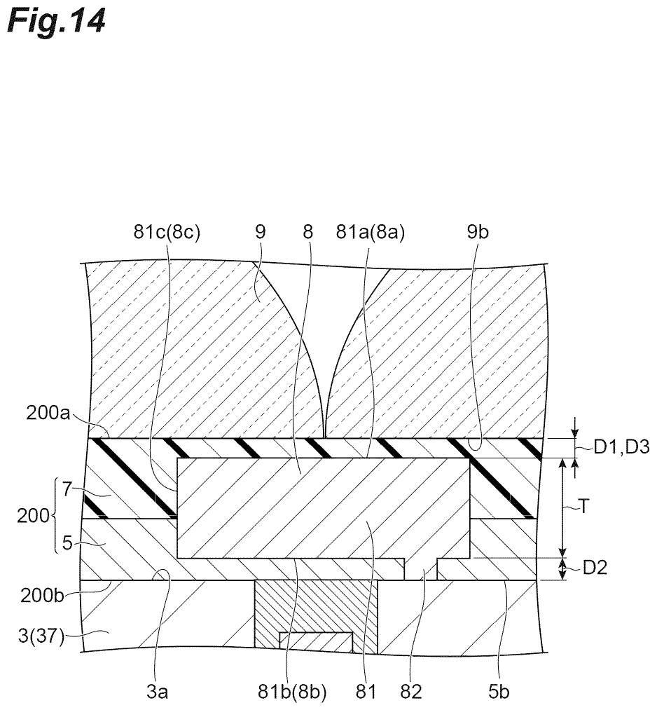

As illustrated in FIGS. 13 and 14, the layer structure 200 does not necessarily include the semiconductor layer 6. In this example, the layer structure 200 includes the insulating layer 5 and the insulating layer 7. That is, the layer structure 200 does not have a layer in which the texture structure 6c is formed. The insulating layer 7 is formed on the main surface 3a of the semiconductor layer 3 with the insulating layer 5 interposed therebetween. The insulating layer 7 is formed directly on the insulating layer 5. The insulating layer 7 is in contact with the main surface 5a of the insulating layer 5. In this example, the insulating layer 5 and the insulating layer 7 are formed of different materials, and a boundary surface exists between the insulating layer 5 and the insulating layer 7.

The metal wiring 8 is located inside the insulating layer 5 and the insulating layer 7. The main body portion 81 of the metal wiring 8 is located inside the insulating layer 5 and the insulating layer 7, and the contact portion 82 of the metal wiring 8 is located inside the insulating layer 5. As illustrated in FIG. 14, the thickness T of the metal wiring 8 is larger than the distance D1 from the surface 8a of the metal wiring 8 to the surface 200a of the layer structure 200 (the main surface 7a of the insulating layer 7). The thickness T is larger than a distance D2 from the surface 8b of the metal wiring 8 to the surface 200b of the layer structure 200 (the main surface 5b of the insulating layer 5). The thickness T is larger than the total of the distance D1 and the distance D2. The thickness T is larger than the distance D3 from the surface 9b of the lens portion 9 to the surface 8a. Since the thickness T of the metal wiring 8 is large also in the light detection element 1 according to the present modification, it is possible to suppress a decrease in detection accuracy for the reason described above.

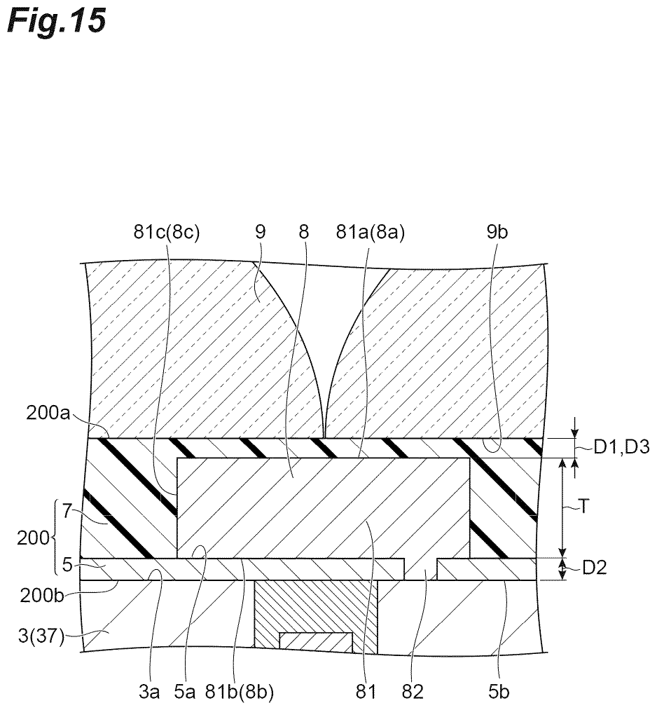

As illustrated in FIG. 15, the main body portion 81 of the metal wiring 8 may be located inside the insulating layer 7 without being located inside the insulating layer 5. That is, the main body portion 81 may be formed on the main surface 5a of the insulating layer 5 such that the entire main body portion 81 is exposed from the insulating layer 5. Also in this example, the thickness T of the metal wiring 8 is larger than the distance D1 from the surface 8a of the metal wiring 8 to the surface 200a of the layer structure 200 (the main surface 7a of the insulating layer 7). The thickness T is larger than a distance D2 from the surface 8b of the metal wiring 8 to the surface 200b of the layer structure 200 (the main surface 5b of the insulating layer 5). The thickness T is larger than the distance D3 from the surface 9b of the lens portion 9 to the surface 8a. Since the thickness T of the metal wiring 8 is large also in the light detection element 1 according to the present modification, it is possible to suppress a decrease in detection accuracy for the reason described above.

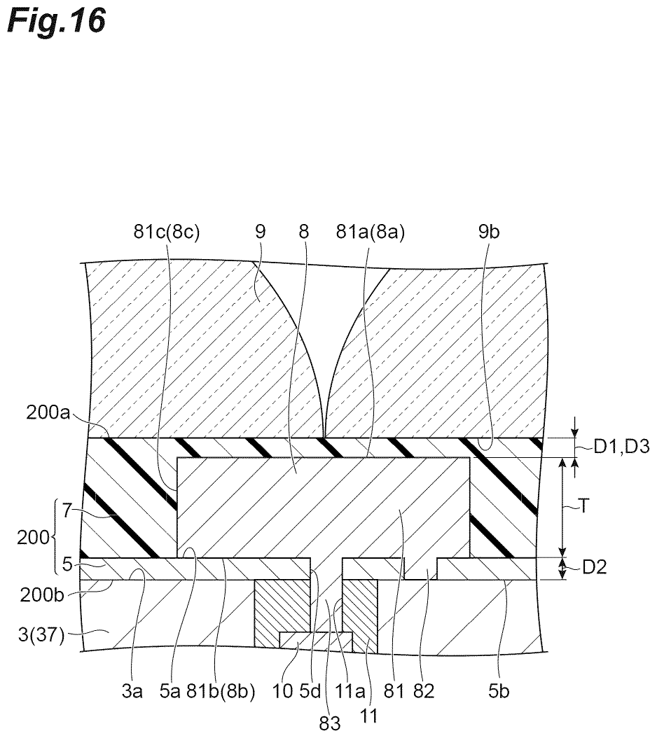

As illustrated in FIG. 16, the metal wiring 8 may further include a wall 83. The wall 83 is formed on the surface 81b of the main body portion 81. The wall 83 is integrally formed with the main body portion 81. The wall 83 extends continuously along the main body portion 81 when viewed from the Z-axis direction. In this example, the wall 83 is formed in a mesh shape when viewed from the Z-axis direction. A through hole 5d is formed in the insulating layer 5, and a through hole 11a is formed in the insulating film 11. Each of the through hole 5d and the through hole 11a has a shape in which the wall 83 can be disposed. That is, each of the through hole 5d and the through hole 11a is continuously formed along the main body portion 81 when viewed from the Z-axis direction. The wall 83 is located inside the through hole 5d and the through hole 11a. The wall 83 is in contact with the metal portion 10. According to the present modification, the crosstalk can be further prevented by the wall 83, and a decrease in detection accuracy can be further suppressed. The shape of the wall portion 83 is not limited, and may be discontinuously (at a specific location) formed when viewed from the Z-axis direction.

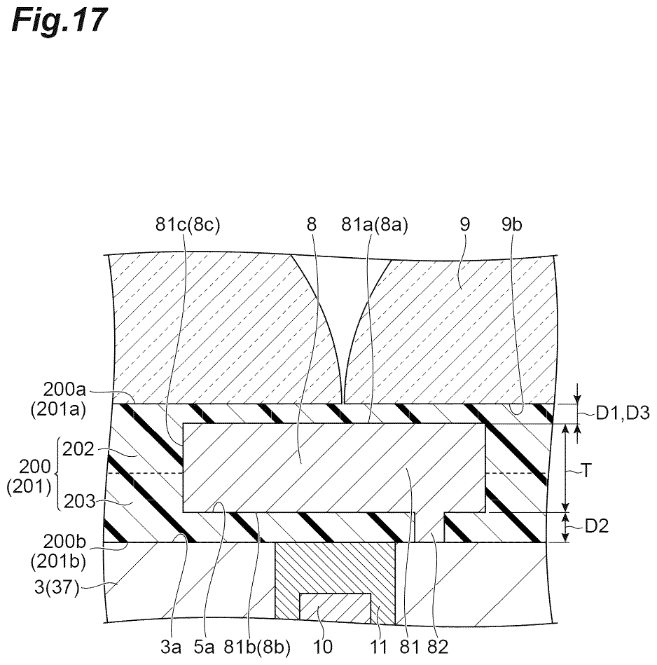

As illustrated in FIG. 17, the layer structure 200 may be a single insulating layer 201. The metal wiring 8 is located inside the single insulating layer 201. The insulating layer 201 may be formed, for example, by stacking a plurality of insulating layers 202 and 203 formed of the same material (for example, SiO₂) and integrating them with each other to such an extent that no boundary surface remains. The insulating layer 201 has a main surface 201a and a main surface 201b. The main surface 201a is a surface of the insulating layer 201 opposite to the semiconductor layer 3, and the main surface 201b is a surface of the insulating layer 201 on the semiconductor layer 3 side. The main surface 201a constitutes a surface 200a of the layer structure 200, and the main surface 201b constitutes a surface 200b of the layer structure 200.

As illustrated in FIG. 17, the thickness T of the metal wiring 8 is larger than the distance D1 from the surface 8a of the metal wiring 8 to the surface 200a of the layer structure 200 (the main surface 201a of the insulating layer 201). The thickness T is larger than the distance D2 from the surface 8b of the metal wiring 8 to the surface 200b of the layer structure 200 (the main surface 201b of the insulating layer 201). The thickness T is larger than the distance D3 from the surface 9b of the lens portion 9 to the surface 8a. Since the thickness T of the metal wiring 8 is large also in the light detection element 1 according to the present modification, it is possible to suppress a decrease in detection accuracy for the reason described above. Furthermore, in the present modification, since the layer structure 200 is the single insulating layer 201, the light detection element 1 can be configured by a simpler design.

In the above embodiment, the quenching element 13 is a passive quenching element including a quenching resistor, but the quenching element 13 may be, for example, an active quenching element (circuit) including a transistor. The position of the quenching element 13 is not limited, and the quenching element 13 may be formed inside the insulating layer 21 or may be formed on the substrate 2.

The texture structure 6c formed in the semiconductor layer 6 may have a regular (constant shape) uneven shape. The texture structure 6c may be formed, for example, by removing a part of the semiconductor layer 6 using a photolithography technique using a mask.

The thickness T of the metal wiring 8 may be equal to or less than the distance D1 from the surface 8a of the metal wiring 8 to the surface 200a of the layer structure 200. The thickness T may be equal to or less than the distance D2 from the surface 8b of the metal wiring 8 to the surface 200b of the layer structure 200. The thickness T may be equal to or less than the distance D3 from the surface 9b of the lens portion 9 to the surface 8a.

A part of the layer structure 200 (the insulating layer 5 in the above embodiment) is not necessarily located between the surface 81b of the metal wiring 8 and the trench 40. In this case, the surface 81b may be in direct contact with the insulating film 11 disposed inside the trench 40, and for example, the insulating layer 5 may be separated into a plurality of portions. When viewed from the Z-axis direction, the metal wiring 8 is not necessarily formed so as to cover the entire trench 40. When viewed from the Z-axis direction, the metal wiring 8 may be formed so as to cover a part of the trench 40. The metal wiring 8 does not necessarily overlap the trench 40 in the Z-axis direction. That is, at least a part of the trench 40 may be exposed from the metal wiring 8 when viewed from the Z-axis direction. The shape of the trench 40 is not limited. For example, the frame portion 41 of the trench 40 may be formed in a polygonal frame shape other than a rectangular frame shape when viewed from the Z-axis direction.

When viewed from the Z-axis direction, the outer edge 9c of each of the plurality of lens portions 9 does not necessarily overlap the trench 40. For example, when viewed from the Z-axis direction, the outer edge 9c of each lens portion 9 may be located inside the corresponding frame portion 41.

The size of the opposite electrode layer 15 may be 50% or less of the size of the semiconductor region 32 when viewed from the Z-axis direction. When viewed from the Z-axis direction, the outer edge 15a of the opposite electrode layer 15 may be located outside the outer edge 32a of the semiconductor region 32.

The shape of the frame region 36 is not limited. For example, the frame region 36 may be formed in a polygonal frame shape other than a rectangular frame shape when viewed from the Z-axis direction. The frame region 36 may be discontinuously formed when viewed from the Z-axis direction. The width W1 of the frame region 36 may be smaller than twice the width W2 of the region A1, or may be equal to or smaller than the width W2. The width W1 may be smaller than twice the width W3 of the region A2, or may be equal to or smaller than the width W3.

In the above-described embodiment and modification, the light detection element 1 may be configured as a SiPM (silicon photomultiplier). Examples of SiPMs include MPPC (multi-pixel photon counter) (registered trademark). In the light detection element 1 configured as the SiPM, a plurality of cell units each including the avalanche photodiode APD and the quenching element 13 are connected in parallel to each other to configure one channel.

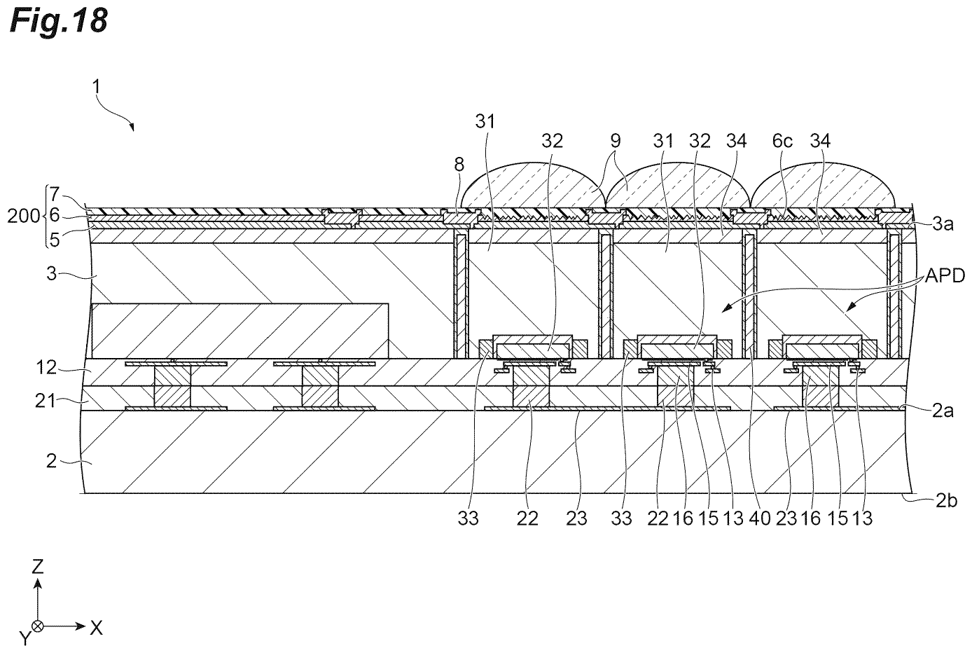

An example of the light detection element 1 configured as a SiPM will be described with reference to FIG. 18. The electrode layer 23 according to the present modification is formed to be larger than the electrode layer 23 according to the first embodiment. In this example, when viewed from the Z-axis direction, each electrode layer 23 is formed so as to overlap a plurality of (four in this example) avalanche photodiodes APD. A plurality of (four in this example) connection conductors 22 are connected to one electrode layer 23. As a result, the plurality of avalanche photodiodes APD are connected in parallel to each other via the electrode layer 23, and the current signals from the respective avalanche photodiodes APD are sent to the substrate 2 in a collected state.

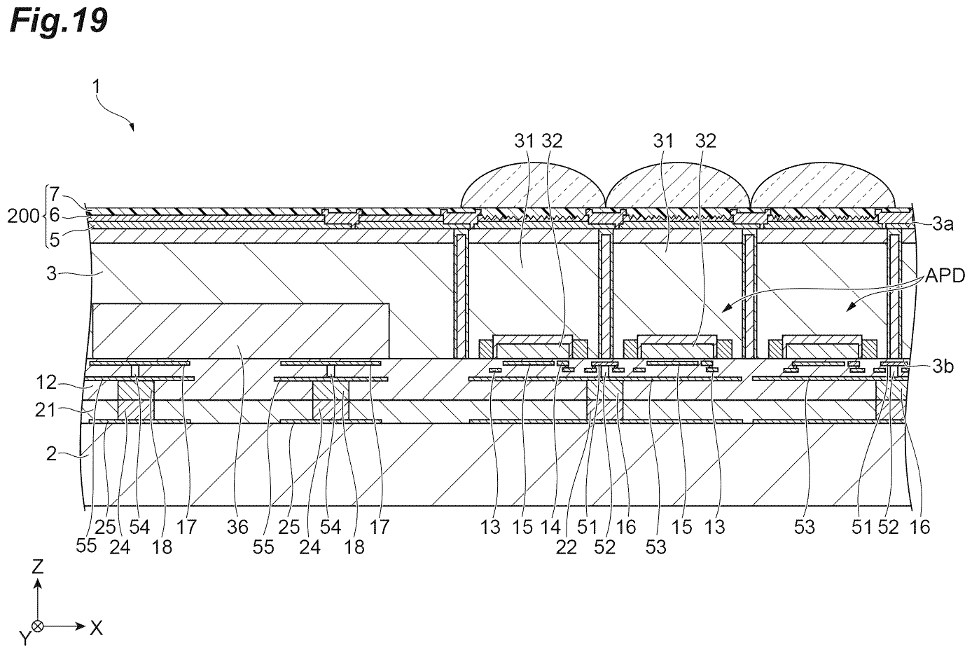

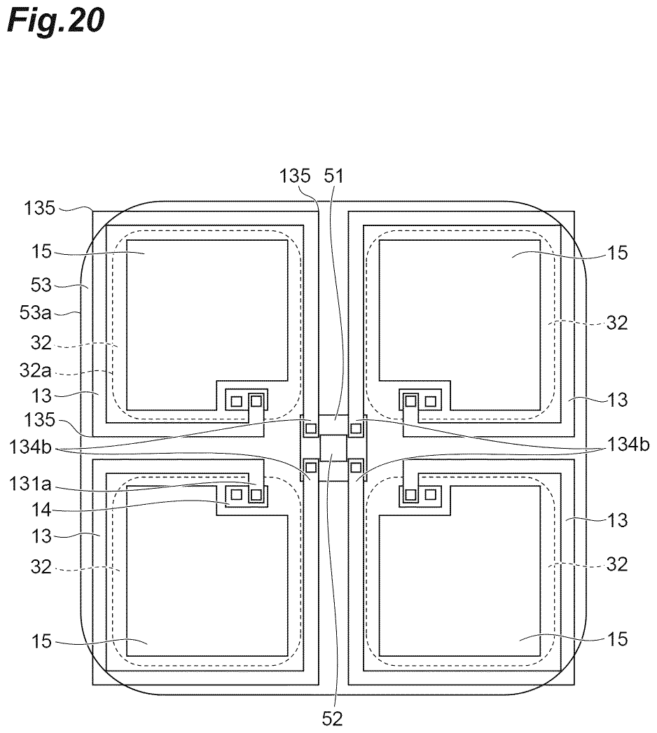

Another example of the light detection element 1 configured as a SiPM will be described with reference to FIGS. 19 and 20. FIG. 20 is a plan view when the light detection element 1 is visually recognized in a direction from the substrate 2 toward the semiconductor layer 3. In FIG. 20, for convenience of description, illustration of a part of the configuration is omitted. The light detection element 1 according to the present modification further includes a plurality of electrode layers 51, a plurality of connection conductors 52, a plurality of opposite electrode layers 53, a plurality of connection conductors 54, and a plurality of electrode layers 55. In FIG. 20, for convenience of description, a part of the configuration overlapping the opposite electrode layer 53 (a portion that cannot be directly visually recognized by the opposite electrode layer 53) is also indicated by a solid line.

In the present modification, one end (end portion 131a) of the quenching element 13 is electrically connected to the semiconductor region 32 via the wiring layer 14, and the other end (end portion 134b) of the quenching element 13 is electrically connected to the electrode layer 51. When viewed from the Z-axis direction, each corner portion 135 is formed at a right angle. The shape of the corner portion 135 is not limited, and may be, for example, another shape such as a round shape illustrated in FIG. 6. The quenching element 13 is not electrically connected to the opposite electrode layer 15. In the present modification, the opposite electrode layer 15 is a floating electrode that is not electrically connected to other wirings, circuits, or the like. In the Z-axis direction, the opposite electrode layer 15 is located at the same height (same layer) as the wiring layer 14.

The plurality of electrode layers 51 are located inside the insulating layer 12. The plurality of electrode layers 51 are located on the main surface 3b side with respect to the semiconductor layer 3. The electrode layer 51 is formed in a rectangular shape when viewed from the Z-axis direction. When viewed from the Z-axis direction, the size of the electrode layer 51 is smaller than the size of the opposite electrode layer 15. In the Z-axis direction, the electrode layer 51 is located at the same height (same layer) as the opposite electrode layer 15. Each electrode layer 51 is located so as to be surrounded by a plurality of (four in this example) opposite electrode layers 15 when viewed from the Z-axis direction. In this example, the end portions 134b of the four quenching elements 13 are connected to one electrode layer 51. The electrode layer 51 is formed of, for example, a metal material such as aluminum.

The plurality of connection conductors 52 are formed inside the insulating layer 12. The plurality of connection conductors 52 are located closer to the substrate 2 than the plurality of electrode layers 51 in the Z-axis direction. Each of the connection conductors 52 is formed in a columnar shape (a cuboid shape in this example) having a central axis along the Z-axis direction. Each connection conductor 52 is electrically connected to the corresponding electrode layer 51 and opposite electrode layer 53. The connection conductor 52 is formed of, for example, a metal material such as copper.

The plurality of opposite electrode layers 53 are located inside the insulating layer 12. The plurality of opposite electrode layers 53 are located on the main surface 3b side with respect to the semiconductor layer 3. The plurality of opposite electrode layers 53 are located closer to the substrate 2 than the quenching element 13 and the connection conductor 52 in the Z-axis direction. Each of the plurality of opposite electrode layers 53 is electrically connected to the corresponding connection conductor 52 and connection conductor 16.

The opposite electrode layer 53 is formed in a substantially rectangular plate shape. When viewed from the Z-axis direction, each corner portion of the opposite electrode layer 53 has a round shape, and is curved so as to protrude toward the outside of the opposite electrode layer 53. The opposite electrode layer 53 faces the plurality of (four in this example) semiconductor regions 32 in the Z-axis direction. The opposite electrode layer 53 overlaps the plurality of semiconductor regions 32 in the Z-axis direction. When viewed from the Z-axis direction, the outer edge 53a of the opposite electrode layer 53 is located outside the outer edges 32a of the plurality of opposing semiconductor regions 32. The opposite electrode layer 53 is formed of, for example, a metal material such as aluminum.

The plurality of connection conductors 54 are formed inside the insulating layer 12. The plurality of connection conductors 54 are located closer to the substrate 2 than the plurality of electrode layers 17 in the Z-axis direction. Each of the connection conductors 54 is formed in a columnar shape having a central axis along the Z-axis direction. Each connection conductor 54 is electrically connected to the corresponding electrode layer 17 and electrode layer 55. The connection conductor 54 is formed of, for example, a metal material such as copper.

The plurality of electrode layers 55 are located inside the insulating layer 12. The plurality of electrode layers 55 are located on the main surface 3b side with respect to the semiconductor layer 3. The plurality of electrode layers 55 are located closer to the substrate 2 than the plurality of connection conductors 54 in the Z-axis direction. In the Z-axis direction, the electrode layer 55 is located at the same height (same layer) as the opposite electrode layer 53. Each electrode layer 55 is electrically connected to the corresponding connection conductor 54 and connection conductor 18. The electrode layer 55 is formed of, for example, a metal material such as aluminum.

In the light detection element 1 according to the present modification, the plurality of avalanche photodiodes APD are connected in parallel to each other via the electrode layer 51, and the current signals from the respective avalanche photodiodes APD are sent to the substrate 2 in a collected state.

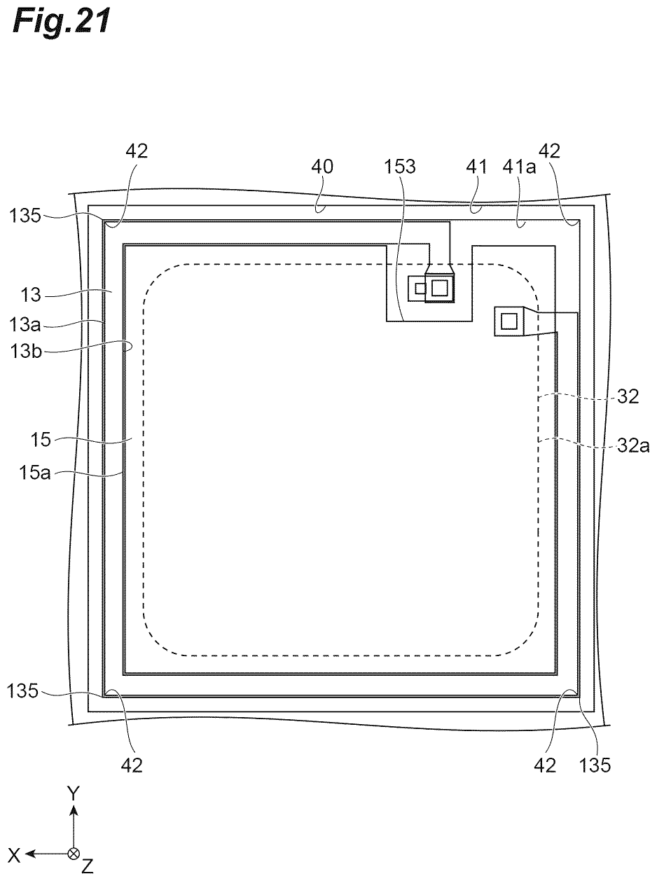

In the above-described embodiment and modification, the quenching element 13, the opposite electrode layer 15, and the semiconductor region 32 may have the configuration illustrated in FIG. 21. In FIG. 21, for convenience of explanation, illustration of a part of the configuration other than the quenching element 13, the opposite electrode layer 15, the semiconductor region 32, and the trench 40 is omitted.

When viewed from the Z-axis direction, the outer edge 15a of the opposite electrode layer 15 is located outside the outer edge 32a of the semiconductor region 32. The outer edge 15a being located outside the outer edge 32a means that 50% or more of the outer edge 15a is located outside the outer edge 32a. In this example, the outer edge 15a is located outside the outer edge 32a except for a portion where the cutout portion 153 is formed.

As compared with the above-described embodiment (for example, the example illustrated in FIG. 6), the outer edge 15a of the opposite electrode layer 15 is located close to the inner edge 13b of the quenching element 13. When viewed from the Z-axis direction, the outer edge 15a may overlap the inner edge 13b. That is, no gap may be formed between the outer edge 15a and the inner edge 13b. When viewed from the Z-axis direction, the outer edge 15a may be located outside the inner edge 13b and overlap the quenching element 13. The outer edge 15a overlapping the inner edge 13b or located outside the inner edge 13b means that 50% or more of the outer edge 15a overlaps the inner edge 13b or is located outside the inner edge 13b.

As compared with the above-described embodiment (for example, the example illustrated in FIG. 6), the outer edge 13a of the quenching element 13 is located closer to the inner edge 41a of the frame portion 41 (trench 40). When viewed from the Z-axis direction, the outer edge 13a may overlap the inner edge 41a. That is, no gap may be formed between the outer edge 13a and the inner edge 41a. When viewed from the Z-axis direction, the outer edge 13a may be located outside the inner edge 41a and overlap the frame portion 41. The outer edge 13a overlapping the inner edge 41a or located outside the inner edge 41a means that 50% or more of the outer edge 13a overlaps the inner edge 41a or is located outside the inner edge 41a.

In the example illustrated in FIG. 21, when viewed from the Z-axis direction, a distance between the outer edge 13a of the quenching element 13 (a portion of the outer edge 13a along the inner edge 41a of the frame portion 41) and the inner edge 41a of the frame portion 41 is smaller than a distance between the outer edge 32a of the semiconductor region 32 and the inner edge 13b of the quenching element 13 (a portion of the inner edge 13b along the outer edge 32a). When viewed from the Z-axis direction, a distance between the inner edge 13b of the quenching element 13 (a portion of the inner edge 13b along the outer edge 15a of the opposite electrode layer 15) and the outer edge 15a of the opposite electrode layer 15 is smaller than a distance between the outer edge 32a of the semiconductor region 32 and the outer edge 15a of the opposite electrode layer 15 (a portion of the outer edge 15a along the outer edge 32a).

In the present modification, when viewed from the Z-axis direction, the outer edge 15a of the opposite electrode layer 15 is located outside the outer edge 32a of the semiconductor region 32. In addition, when viewed from the Z-axis direction, the distance between the inner edge 13b of the quenching element 13 and the outer edge 15a of the opposite electrode layer 15 is smaller than the distance between the outer edge 32a of the semiconductor region 32 and the outer edge 15a of the opposite electrode layer 15. As a result, the area of the opposite electrode layer 15 becomes larger, and the light passing through the semiconductor layer 3 can be more reliably reflected toward the semiconductor region 32 (the amount of reflected light can be increased).

In the present modification, when viewed from the Z-axis direction, a distance between the outer edge 13a of the quenching element 13 and the inner edge 41a of the frame portion 41 is smaller than a distance between the outer edge 32a of the semiconductor region 32 and the inner edge 13b of the quenching element 13. As a result, since the quenching element 13 is formed on the outer side when viewed from the Z-axis direction, the quenching element 13 can be formed long, and the recovery time can be improved (shortened) even when the pitch between the plurality of cell units (pixels) including the avalanche photodiode APD is small.

What is claimed is:

1. A light detection element comprising:
a first semiconductor layer having a first main surface as a light incident surface and a second main surface opposite to the first main surface;
a layer structure formed on the first main surface;
metal wiring formed on the first main surface and at least partially located inside the layer structure; and
a plurality of quenching elements located on the second main surface side with respect to the first semiconductor layer, wherein
the first semiconductor layer includes
a plurality of first semiconductor regions of a first conductivity type,
a plurality of second semiconductor regions of a second conductivity type located closer to the second main surface than the plurality of first semiconductor regions and constituting a plurality of avalanche photodiodes together with the plurality of first semiconductor regions, and
a plurality of third semiconductor regions of the first conductivity type located closer to the first main surface than the plurality of first semiconductor regions and having an impurity concentration higher than an impurity concentration of the plurality of first semiconductor regions,
each of the plurality of quenching elements is electrically connected to a corresponding second semiconductor region among the plurality of second semiconductor regions,
a trench extending so as to separate the plurality of third semiconductor regions from each other is formed in the first semiconductor layer,
the metal wiring is formed on the first main surface so as to extend along the trench, and electrically connects the plurality of third semiconductor regions to each other, and
a thickness of the metal wiring is larger than a distance from a first surface of the metal wiring on a side opposite to the first main surface to a surface of the layer structure on a side opposite to the first main surface, and is larger than a distance from a second surface of the metal wiring on a side of the first main surface to a surface of the layer structure on a side of the first main surface.

2. The light detection element according to claim 1, wherein
the layer structure includes a first insulating layer formed on the first main surface and a second insulating layer formed on the first insulating layer, and
the metal wiring is located inside the first insulating layer and the second insulating layer.

3. The light detection element according to claim 2, wherein
a side surface of the metal wiring is in contact with the first insulating layer and the second insulating layer.

4. The light detection element according to claim 1, wherein
the layer structure is a single insulating layer.

5. The light detection element according to claim 1, further comprising
a lens portion disposed on the layer structure.

6. The light detection element according to claim 5, wherein
a thickness of the metal wiring is larger than a distance from a surface of the lens portion on a side of the first main surface to the first surface.

7. The light detection element according to claim 5, further comprising
a plurality of lens portions each configured to be the lens portion, wherein
each of the plurality of lens portions is disposed so as to overlap a corresponding avalanche photodiode among the plurality of avalanche photodiodes in a direction perpendicular to the first main surface, and
an outer edge of each of the plurality of lens portions overlaps the trench when viewed from the direction perpendicular to the first main surface.

8. The light detection element according to claim 1, wherein
the metal wiring is formed so as to cover the entire trench when viewed from a direction perpendicular to the first main surface, and
each of the plurality of avalanche photodiodes is surrounded by the metal wiring when viewed from the direction perpendicular to the first main surface.

9. A light detection element comprising:
a first semiconductor layer having a first main surface as a light incident surface and a second main surface opposite to the first main surface;
a layer structure having a first insulating layer formed on the first main surface, and a second insulating layer formed on the first insulating layer;
metal wiring formed on the first main surface, at least a part of which is located inside the layer structure; and
a plurality of quenching elements located on the second main surface side with respect to the first semiconductor layer, wherein
the first semiconductor layer includes
a plurality of first semiconductor regions of a first conductivity type,
a plurality of second semiconductor regions of a second conductivity type located closer to the second main surface than the plurality of first semiconductor regions and constituting a plurality of avalanche photodiodes together with the plurality of first semiconductor regions, and
a plurality of third semiconductor regions of the first conductivity type located closer to the first main surface than the plurality of first semiconductor regions and having an impurity concentration higher than an impurity concentration of the plurality of first semiconductor regions,
each of the plurality of quenching elements is electrically connected to a corresponding second semiconductor region among the plurality of second semiconductor regions,
a trench extending so as to separate the plurality of third semiconductor regions from each other is formed in the first semiconductor layer,
the metal wiring is formed on the first main surface so as to extend along the trench, and electrically connects the plurality of third semiconductor regions to each other, and
a surface of the metal wiring on a side opposite to the first main surface is located farther from the first main surface than a surface of the first insulating layer on a side opposite to the first semiconductor layer in a direction perpendicular to the first main surface.
